(19) United States
(12) Patent Application Publication
(10) Pub. No.: US 2026/0150264 A1
(43) Pub. Date: May 28, 2026

(54) THREE-DIMENSIONAL MEMORY DEVICE AND METHOD FOR FORMING THE SAME

(71) Applicant: Yangtze Memory Technologies Co., Ltd., Wuhan (CN)

(72) Inventors: Zongliang Huo, Wuhan (CN); Wei Xu, Wuhan (CN); Jiyue Song, Wuhan (CN); Qiangwei Zhang, Wuhan (CN); Zongke Xu, Wuhan (CN)

(21) Appl. No.: 19/016,926

(22) Filed: Jan. 10, 2025

(30) Foreign Application Priority Data
Nov. 27, 2024 (WO) PCT/CN2024/134870
Nov. 29, 2024 (CN) 202411750482.2

(51) Int. Cl. H10B 12/00; H01L 23/00; H01L 25/00; H01L 25/065; H01L 25/18; H10B 80/00

(52) U.S. Cl. CPC H10B 12/315; H10B 12/033; H10B 80/00; H10W 90/00; H10W 80/312; H10W 80/327; H10W 90/792

(57) ABSTRACT

A memory device, a memory system, and a fabrication method are provided. The memory device includes a first semiconductor structure including a memory cell array in a memory array region of the first semiconductor structure. The memory cell array includes an array of transistors and an array of storage units which connect to corresponding transistors. The first semiconductor structure further includes an isolation structure located between the memory array region and a contact region of the first semiconductor structure. The isolation structure isolates the array of storage units in the memory array region from the contact region.

### CROSS-REFERENCE TO RELATED APPLICATIONS

This application claims the benefit of priority to International Application No. PCT/CN 2024/134870, filed on Nov. 27, 2024, and Chinese Application No. 202411750482.2, filed on Nov. 29, 2024, both of which are incorporated herein by reference in their entireties.

### TECHNICAL FIELD

The present disclosure generally relates to the field of semiconductor technology, and more particularly, to semiconductor devices and fabrication methods thereof.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a memory device includes a first semiconductor structure including a memory cell array in a memory array region of the first semiconductor structure. The memory cell array includes an array of transistors and an array of storage units which connect to corresponding transistors. The first semiconductor structure further includes an isolation structure located between the memory array region and a contact region of the first semiconductor structure. The isolation structure isolates the array of storage units in the memory array region from the contact region.

In some implementations, the first semiconductor structure further includes a stack structure including alternating first layers and first dielectric layers in the contact region.

In some implementations, the first dielectric layers include a first dielectric material, and the first layers include second dielectric layers that include a second dielectric material.

In some implementations, the first dielectric layers include a first dielectric material; and the first layers include at least a second dielectric layer that includes a second dielectric material and a third dielectric layer that includes a third dielectric material.

In some implementations, the first semiconductor structure further includes a first contact structure extending through the stack structure in a first direction. An end surface of the first contact structure that is on a first one of the first layers is flush with an end surface of the isolation structure that is on the first one of the first layers.

In some implementations, the first semiconductor structure further includes: a second contact structure extending through the stack structure in the first direction and coupled to a word line; and a third contact structure extending through the stack structure in the first direction and coupled to a bit line. An end surface of the second contact structure that is on the first one of the first layers is flush with an end surface of the third contact structure that is on the first one of the first layers.

In some implementations, a size of the end surface of the second contact structure is equal to a size of the end surface of the third contact structure.

In some implementations, a size of the end surface of the first contact structure is greater than the size of the end surface of the second contact structure and the size of the end surface of the third contact structure; or, the size of the end surface of the isolation structure is greater than the size of the end surface of the second contact structure and the size of the end surface of the third contact structure.

In some implementations, a size of the end surface of the first contact structure is equal to a size of the end surface of the isolation structure.

In some implementations, a size of the end surface of the first contact structure is different from a size of the end surface of the isolation structure.

In some implementations, the isolation structure includes a dielectric material, and the first contact structure includes a conductive material.

In some implementations, the memory device further includes a second semiconductor structure bonded with the first semiconductor structure. The second semiconductor structure includes a peripheral circuit coupled with the memory cell array.

In some implementations, the transistors include vertical transistors, and the storage units include vertical capacitors.

In some implementations, the vertical capacitor includes: a first electrode structure coupled with a corresponding vertical transistor; and a second electrode structure isolated from the first electrode structure. An end surface of the first electrode structure that is on the first one of the first layers is flush with the end surface of the second contact structure and the end surface of the third contact structure.

In some implementations, a size of the end surface of the first electrode structure is equal to a size of the end surface of the second contact structure and a size of the end surface of the third contact structure.

In another aspect, a memory device is disclosed. The memory device includes a first semiconductor structure including a memory cell array in a memory array region of the first semiconductor structure. The memory cell array includes an array of vertical transistors and an array of vertical capacitors which connect to corresponding vertical transistors. The first semiconductor structure further includes a stack structure including alternating first layers and first dielectric layers in a contact region of the first semiconductor structure. The first semiconductor structure further includes an isolation structure located between the memory array region and the contact region to isolate the array of vertical capacitors from the stack structure.

In some implementations, the first dielectric layers include a first dielectric material, and the first layers include second dielectric layers that include a second dielectric material.

In some implementations, the first dielectric layers include a first dielectric material; and the first layers include at least a second dielectric layer that includes a second dielectric material and a third dielectric layer that includes a third dielectric material.

In some implementations, the first semiconductor structure further includes a first contact structure extending through the stack structure in a first direction. An end surface of the first contact structure that is on a first one of the first layers is flush with an end surface of the isolation structure that is on the first one of the first layers.

In some implementations, the first semiconductor structure further includes: a second contact structure extending through the stack structure in the first direction and coupled to a word line; and a third contact structure extending through the stack structure in the first direction and coupled to a bit line. An end surface of the second contact structure that is on the first one of the first layers is flush with an end surface of the third contact structure that is on the first one of the first layers.

In some implementations, a size of the end surface of the second contact structure is equal to a size of the end surface of the third contact structure.

In some implementations, a size of the end surface of the first contact structure is greater than the size of the end surface of the second contact structure and the size of the end surface of the third contact structure; or, the size of the end surface of the isolation structure is greater than the size of the end surface of the second contact structure and the size of the end surface of the third contact structure.

In some implementations, a size of the end surface of the first contact structure is equal to a size of the end surface of the isolation structure.

In some implementations, a size of the end surface of the first contact structure is different from a size of the end surface of the isolation structure.

In some implementations, the isolation structure includes a dielectric material, and the first contact structure includes a conductive material.

In some implementations, the memory device further includes a second semiconductor structure bonded with the first semiconductor structure. The second semiconductor structure includes a peripheral circuit coupled with the memory cell array.

In some implementations, the vertical capacitor includes: a first electrode structure coupled with the corresponding vertical transistor; and a second electrode structure isolated from the first electrode structure. An end surface of the first electrode structure that is on the first one of the first layers is flush with the end surface of the second contact structure and the end surface of the third contact structure.

In some implementations, a size of the end surface of the first electrode structure is equal to a size of the end surface of the second contact structure and a size of the end surface of the third contact structure.

In still another aspect, a method for forming a memory device is disclosed. The method includes forming a first semiconductor structure at least by forming a memory cell array in a memory array region of the first semiconductor structure. Forming the memory cell array includes forming an array of transistors in the memory array region, and forming, in the memory array region, an array of storage units which connect to corresponding transistors. Forming the first semiconductor structure further includes forming an isolation structure between the memory array region and a contact region of the first semiconductor structure to isolate the array of storage units in the memory array region from the contact region.

In some implementations, forming the first semiconductor structure further includes forming a stack structure including alternating first layers and first dielectric layers across the memory array region and the contact region.

In some implementations, forming the first semiconductor structure further includes: forming a first contact opening, a second contact opening, and a third contact opening extending through the stack structure in a first direction in the contact region; forming storage openings extending through the stack structure in the first direction in the memory array region; and forming an isolation opening extending through the stack structure in the first direction between the memory array region and the contact region.

In some implementations, forming the isolation structure includes forming the isolation structure in the isolation opening.

In some implementations, forming the first semiconductor structure further includes: forming a first contact structure in the first contact opening; forming a second contact structure in the second contact opening to couple to a word line; and forming a third contact structure in the third contact opening to couple to a bit line. An end surface of the first contact structure that is on a first one of the first layers is flush with an end surface of the isolation structure that is on the first one of the first layers. An end surface of the second contact structure that is on the first one of the first layers is flush with an end surface of the third contact structure that is on the first one of the first layers.

In some implementations, the storage units include vertical capacitors, and forming the array of storage units includes: forming first electrode structures in the storage openings, respectively, where the first electrode structures are coupled with the transistors, respectively; and forming second electrode structures isolated from the first electrode structures. The vertical capacitor includes a corresponding first electrode structure and a corresponding second electrode structure.

In some implementations, forming the second electrode structures isolated from the first electrode structures includes: forming a storage recess in the memory array region; and forming the second electrode structures isolated from the first electrode structures in the storage recess.

In some implementations, forming the storage recess in the memory array region includes: forming first mesh openings extending through a first one of the first layers in the memory array region; removing a first part of a first one of the first dielectric layers in the memory array region through the first mesh openings, where a remaining part of the first one of the first dielectric layers in the contact region is isolated by the isolation structure and remains intact; forming second mesh openings extending through a second one of the first layers in the memory array region; and removing a part of a second one of the first dielectric layers in the memory array region through the second mesh openings, where a remaining part of the second one of the first dielectric layers in the contact region is isolated by the isolation structure and remains intact.

In some implementations, forming the second electrode structures isolated from the first electrode structures includes: forming a storage dielectric layer to cover the first electrode structures in the storage recess; and forming the second electrode structures in the storage recess by depositing conductive layers over the storage dielectric layer.

In some implementations, the method further includes: forming a second semiconductor structure; and bonding the second semiconductor structure with the first semiconductor structure. The second semiconductor structure includes a peripheral circuit coupled with the memory cell array.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic view of a cross-section of a 3D memory device, according to some aspects of the present disclosure.

FIG. 1B illustrates a schematic circuit diagram of a memory device including peripheral circuits and an array of dynamic random-access memory (DRAM) cells, according to some aspects of the present disclosure.

FIG. 2A illustrates a side view of a cross section of a memory device, according to some examples of the present disclosure.

FIG. 2B illustrates a plan view of a cross section of a memory device, according to some examples of the present disclosure.

FIGS. 3A-3M illustrate a fabrication process for forming a memory device, according to some examples of the present disclosure.

FIG. 4A illustrates a side view of cross sections of a memory device, according to some aspects of the present disclosure.

FIG. 4B illustrates a plan view of a cross section of a memory device, according to some aspects of the present disclosure.

FIG. 4C illustrates an enlarged view of vertical capacitors, according to some aspects of the present disclosure.

FIG. 4D illustrates another side view of cross sections of a memory device, according to some aspects of the present disclosure.

FIGS. 5A-5Z and 6A-6B illustrate a fabrication process for forming a memory device, according to some aspects of the present disclosure.

FIG. 7A illustrates a flowchart of a method for forming a 3D memory device, according to some aspects of the present disclosure.

FIG. 7B illustrates a flowchart of a method for forming a first semiconductor structure, according to some aspects of the present disclosure.

FIG. 8 illustrates a block diagram of an exemplary system having a 3D memory device, according to some aspects of the present disclosure.

FIG. 9A illustrates a diagram of an exemplary memory card having a 3D memory device, according to some aspects of the present disclosure.

FIG. 9B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features, as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

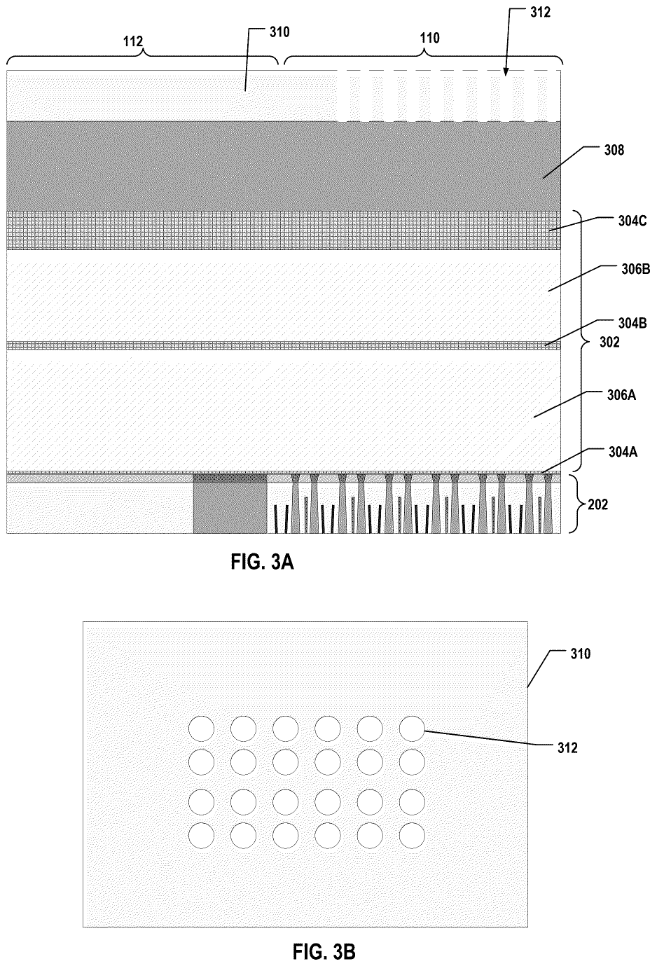

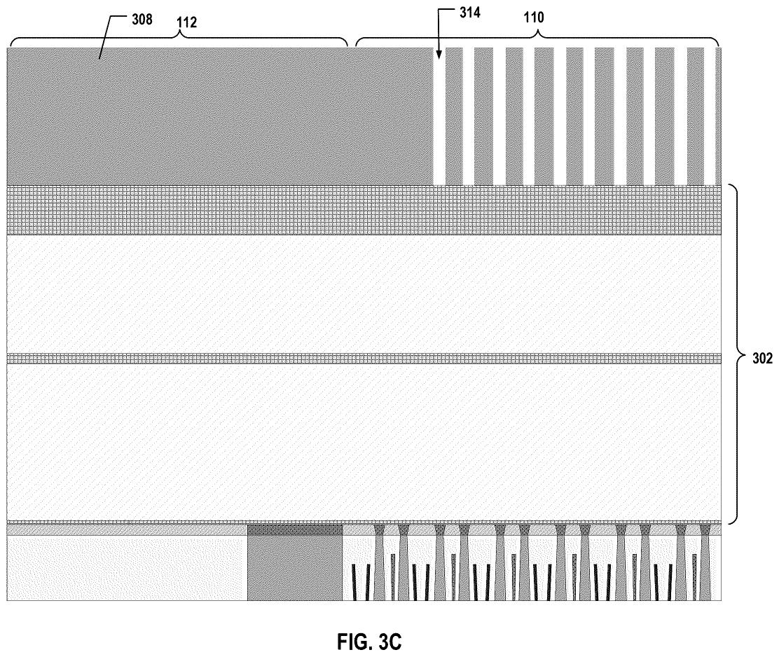

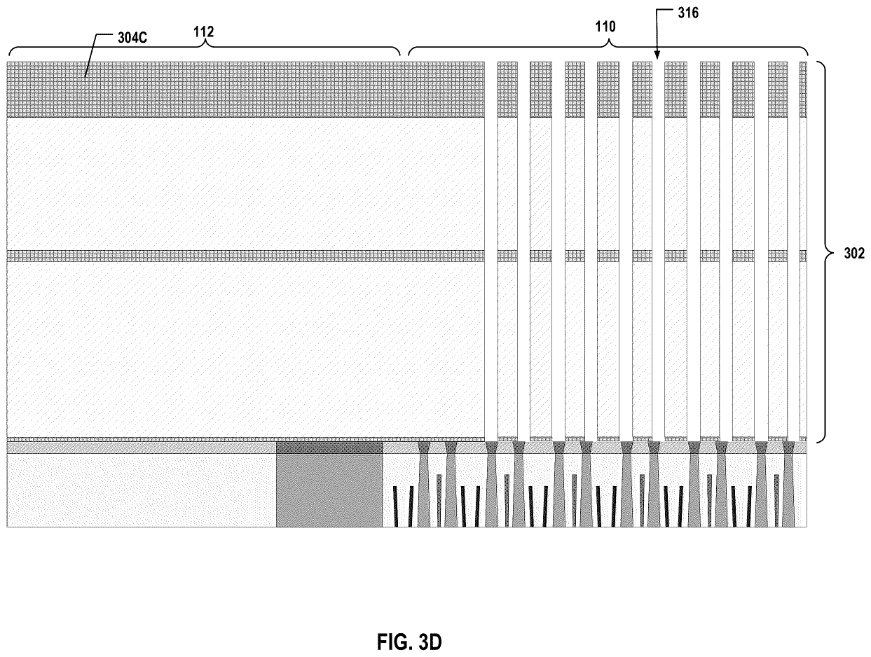

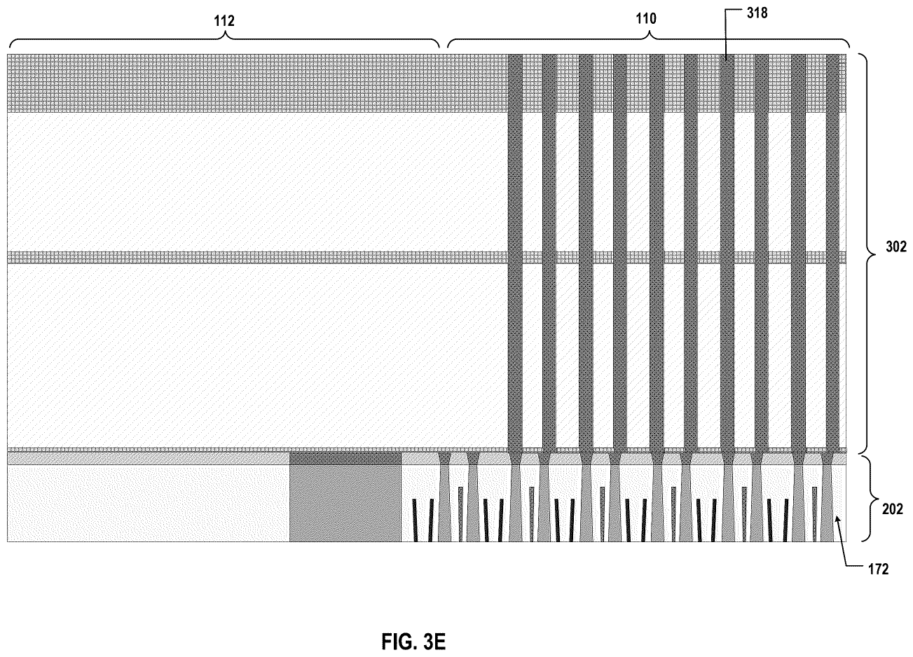

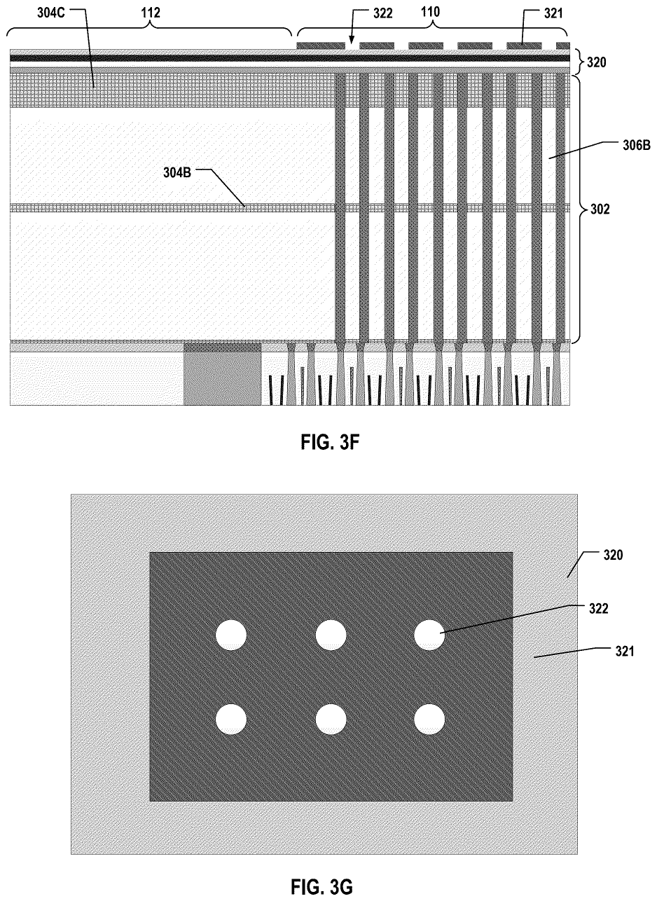

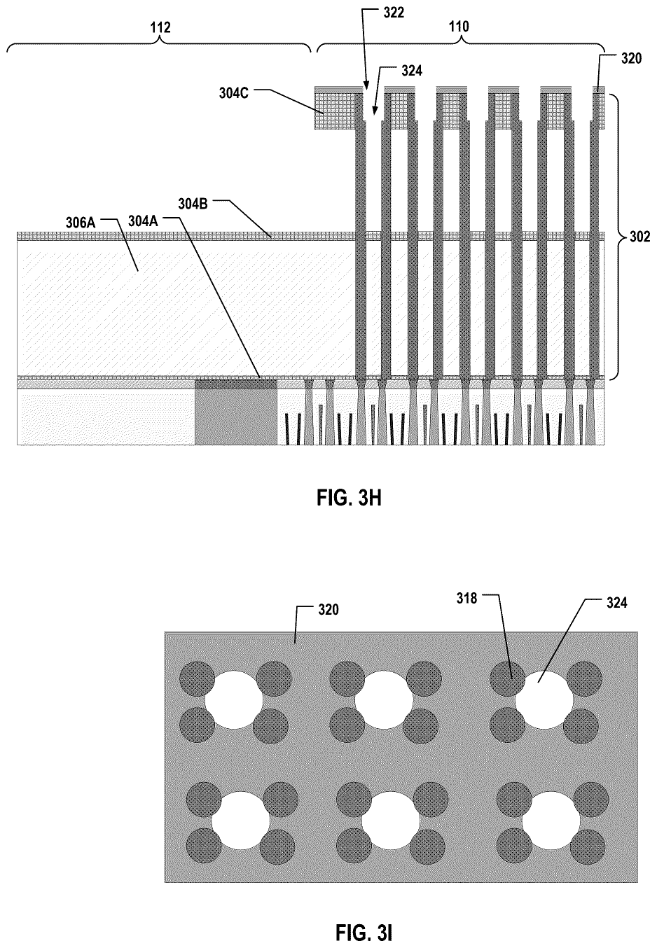

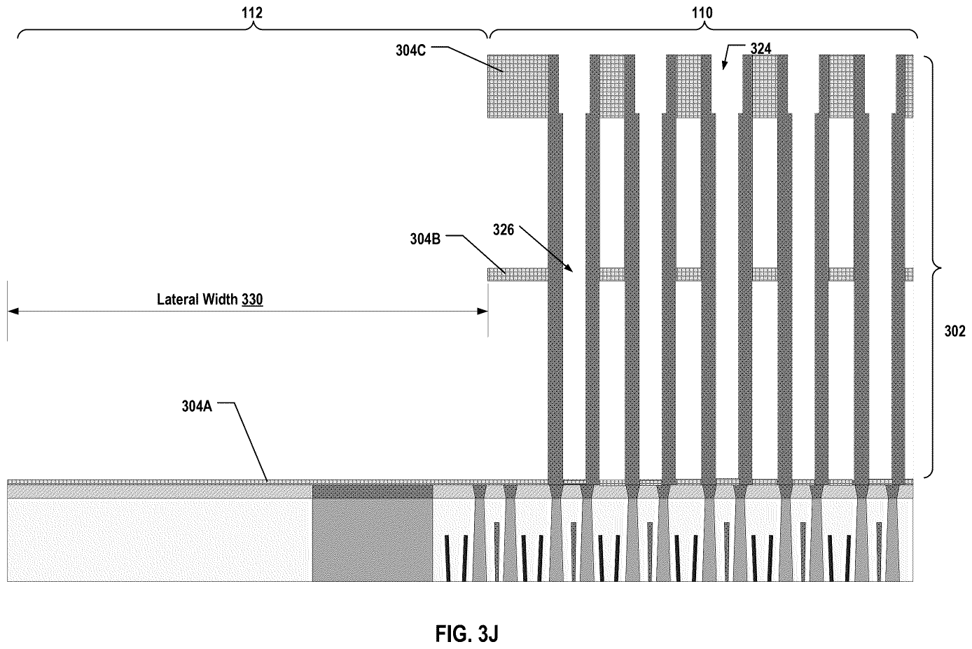

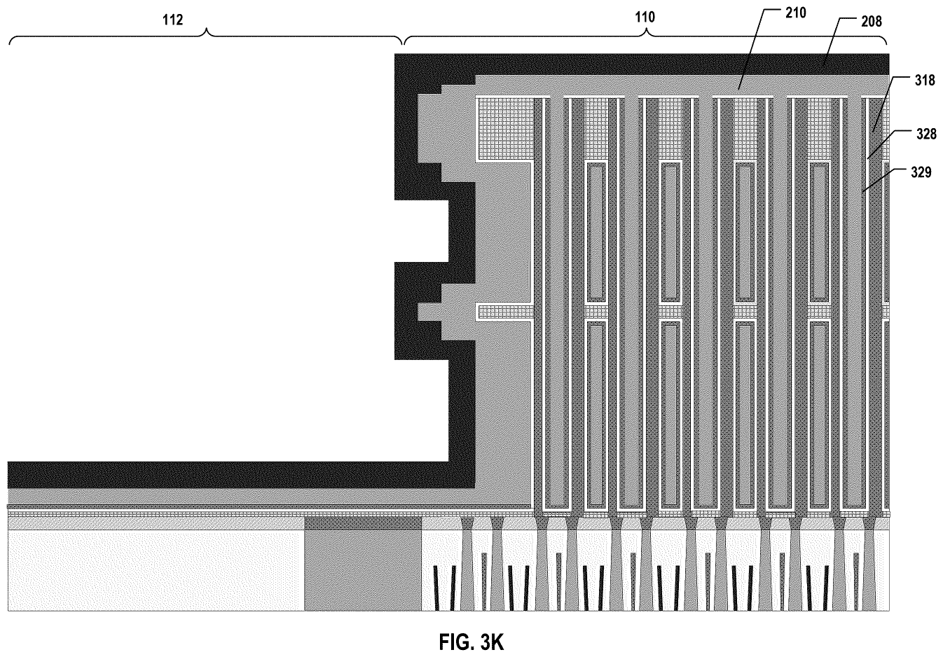

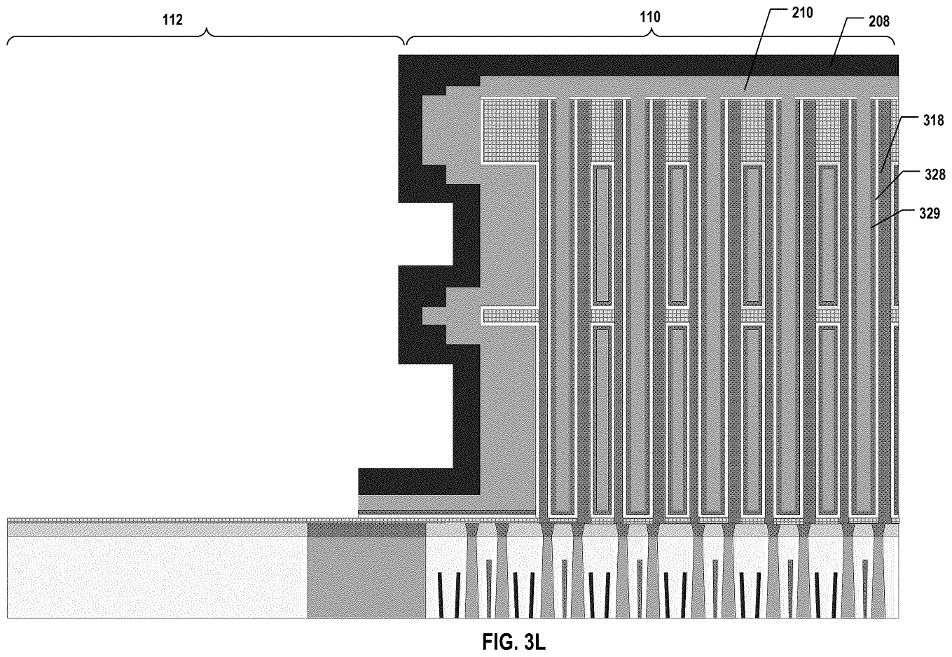

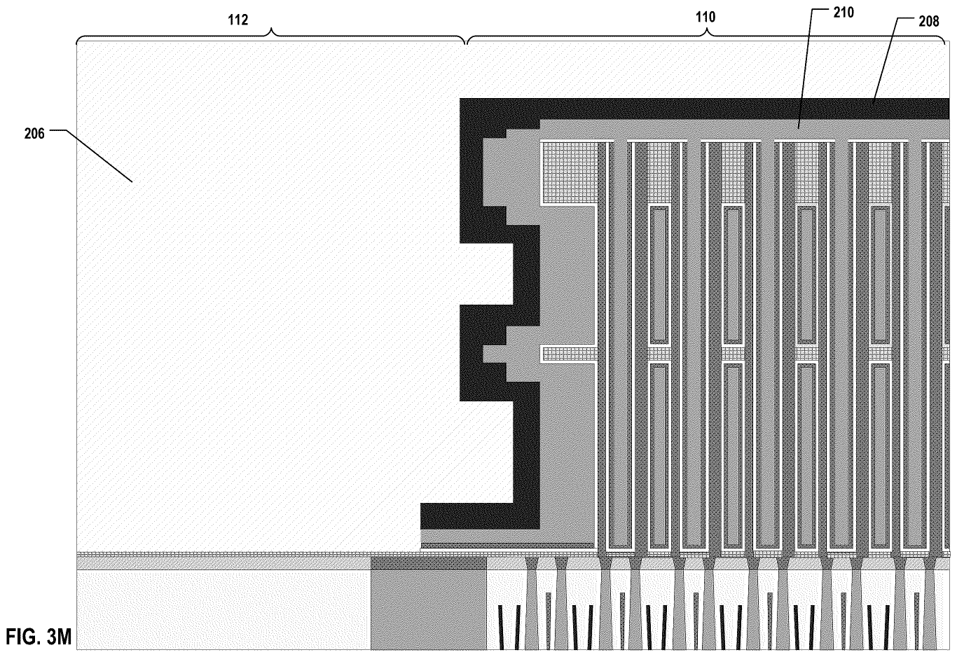

In some examples, a memory device may be divided into memory array regions and a contact region, where the memory array regions are separated from one another by the contact region (e.g., the memory array regions are surrounded by the contact region). Memory cell arrays may be formed in the respective memory array regions, and a dielectric material (e.g., a silicon oxide) may be filled in the entire contact region to isolate the memory cell arrays from one another. However, to fill the contact region with the dielectric material, a stack structure which is previously formed in the contact region needs to be removed (e.g., as shown in FIGS. 3H-3J below). This removal of the stack structure in the contact region and the refilling of the dielectric material in the contact region may result in a high manufacturing cost. Additionally, a lateral width (e.g., a lateral width 330 shown in FIG. 3J) for removing the stack structure in the contact region is large, which may result in a waste in the space between the memory cell arrays.

To address one or more of the aforementioned issues, the present disclosure introduces a solution in which an isolation structure may be formed between a memory array region and a contact region of a memory device to isolate the memory array region from the contact region. A memory cell array may be formed in the memory array region, whereas a contact structure may be formed in a stack structure in the contact region. Due to the existence of the isolation structure, the stack structure in the contact region does not need to be removed (e.g., the stack structure in the contact region remains intact), and therefore, there is no need to refill the contact region with a dielectric material again to achieve the isolation of the memory cell array. As a result, the manufacturing cost can be reduced, and the space between memory cell arrays can be saved.

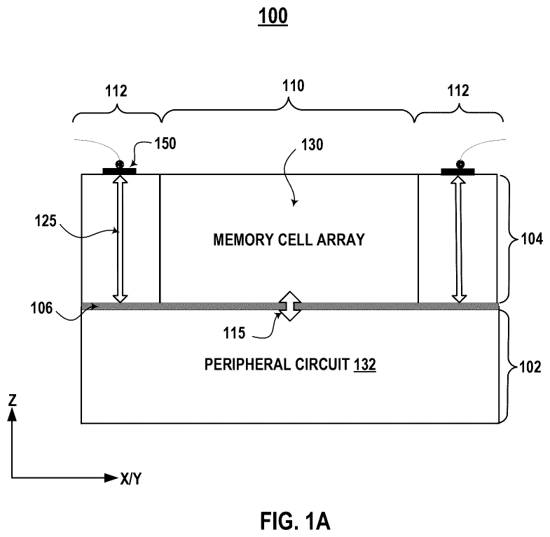

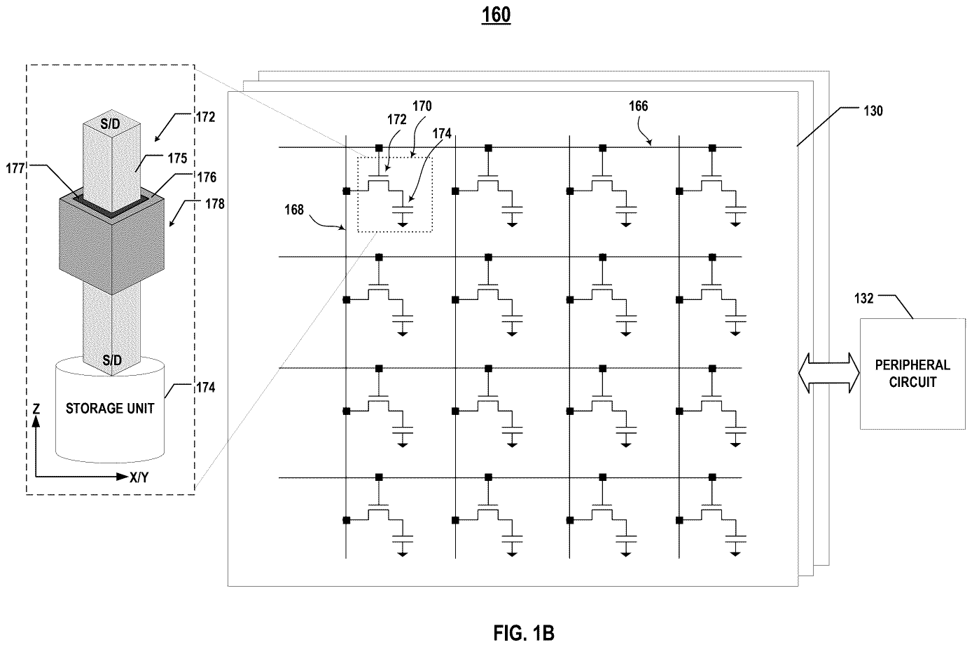

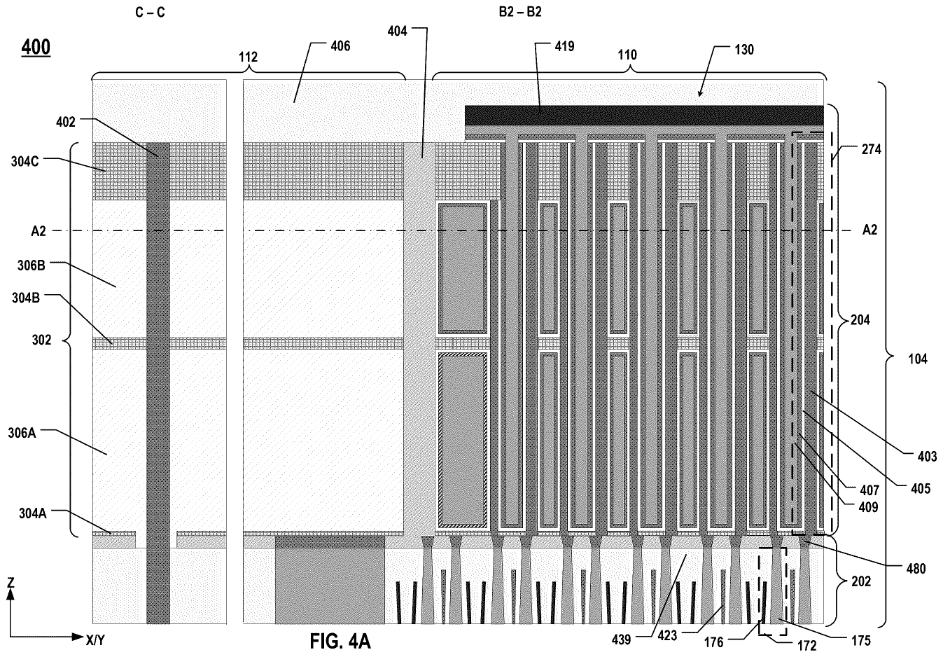

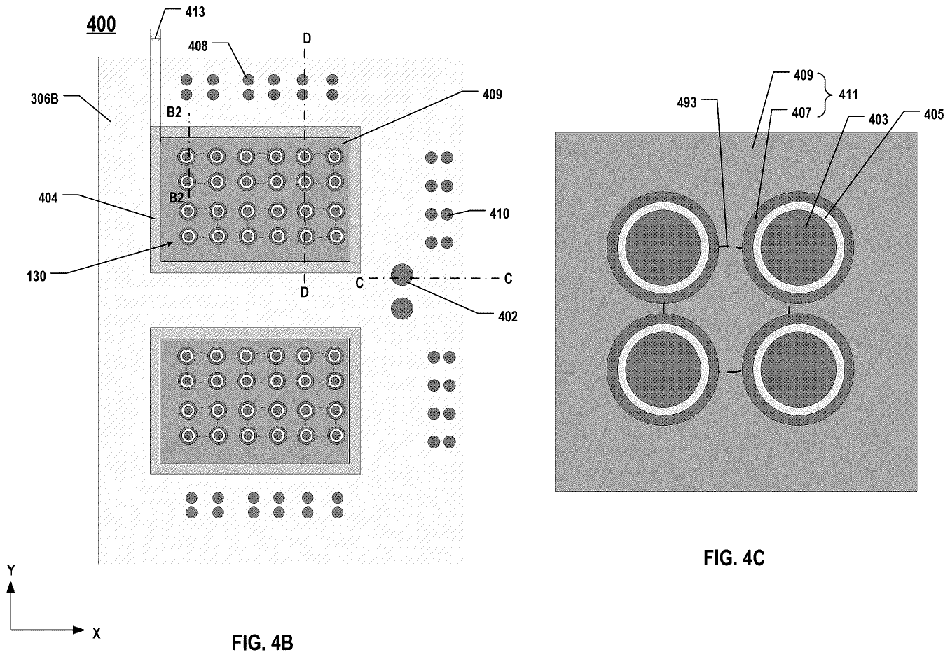

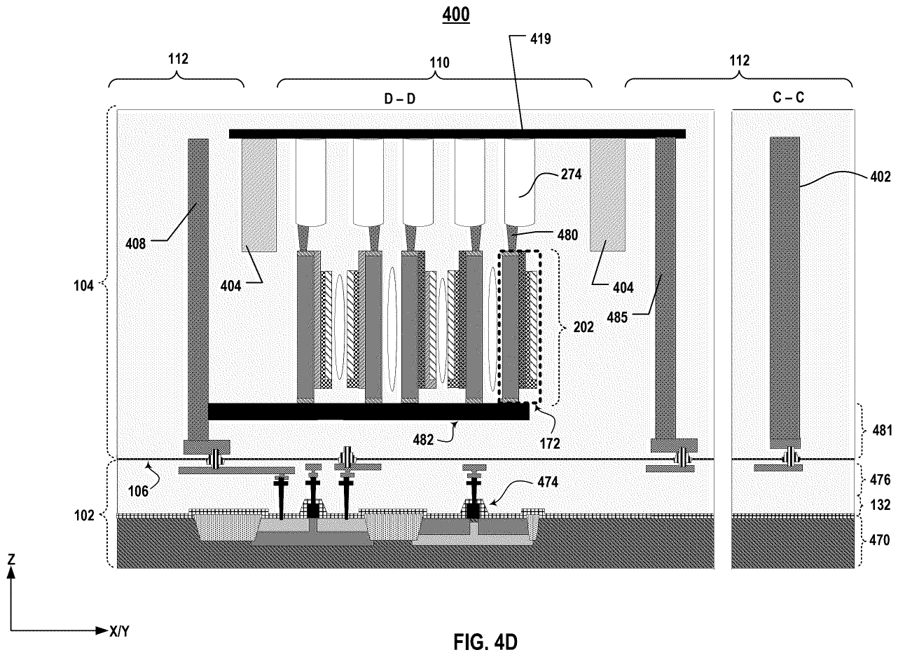

FIG. 1A illustrates a schematic view of a cross section of a 3D memory device 100, according to some aspects of the present disclosure. 3D memory device 100 represents an example of a bonded chip. The components of 3D memory device 100 (e.g., a memory cell array 130 and peripheral circuits 132) can be formed separately on different substrates and then jointed to form a bonded chip. 3D memory device 100 can include a first semiconductor structure 104 (also referred to as a memory structure) and a second semiconductor structure 102 (also referred to as a circuit structure). First semiconductor structure 104 may include memory cell array 130 in a memory array region 110 and one or more contact structures 125 (e.g., contact structures 402, 408, 410, and 485 described below with reference to FIGS. 4A-4D) in a contact region 112. Second semiconductor structure 102 may include peripheral circuits 132 of memory cell array 130.

Peripheral circuits 132 (a.k.a. control and sensing circuits) can include any suitable digital, analog, and/or mixed-signal circuits used for facilitating the operations of memory cell array 130. For example, peripheral circuits 132 can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). Peripheral circuits 132 in second semiconductor structure 102 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

In some implementations, first semiconductor structure 104 can include an array of memory cells (memory cell array 130) that can use transistors as the switch and selecting devices. In some implementations, memory cell array 130 includes an array of DRAM cells. For ease of description, a DRAM cell array may be used as an example for describing memory cell array 130 in the present disclosure. But it is understood that memory cell array 130 is not limited to DRAM cell array and may include any other suitable types of memory cell arrays that can use transistors as the switch and selecting devices, such as phase-change memory (PCM) cell array, static random-access memory (SRAM) cell array, Ferroelectric Random Access Memory (FRAM) cell array, resistive memory cell array, magnetic memory cell array, spin transfer torque (STT) memory cell array, to name a few, or any combination thereof.

In some implementations, first semiconductor structure 104 can be a DRAM device in which memory cells are provided in the form of an array of DRAM cells. The DRAM cell includes a capacitor for storing a bit of data as a positive or negative electrical charge as well as one or more transistors (a.k.a. pass transistors) that control (e.g., switch and selecting) access to it. In some implementations, the DRAM cell is a one-transistor, one-capacitor (1T1C) cell. Since transistors always leak a small amount of charge, the capacitors will slowly discharge, causing information stored in them to drain. As such, a DRAM cell has to be refreshed to retain data, for example, by peripheral circuits 132 in second semiconductor structure 102, according to some implementations.

As shown in FIGS. 1A, 3D memory device 100 further includes a bonding interface 106 vertically between (in the vertical direction, e.g., the z-direction in FIG. 1A) second semiconductor structure 102 and first semiconductor structure 104. As described below in more detail, first semiconductor structure 104 and second semiconductor structure 102 can be fabricated separately (and in parallel in some implementations) such that the thermal budget of fabricating one of semiconductor structures 102 and 104 does not limit the processes of fabricating another one of semiconductor structures 102 and 104. Moreover, a large number of interconnects 115 (e.g., bonding contacts) can be formed through bonding interface 106 to make direct, short-distance (e.g., micron-level) electrical connections between second semiconductor structure 102 and first semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between memory cell array 130 in first semiconductor structure 104 and peripheral circuits 132 in second semiconductor structure 102 can be performed through interconnects 115 (e.g., bonding contacts) across bonding interface 106. By vertically integrating first and second semiconductor structures 104 and 102, the chip size can be reduced, and the memory cell density can be increased.

In some implementations as shown in FIG. 1A, first semiconductor structure 104 can further include a contact region 112 surrounding memory array region 110. One or more contact structures 125 can extend vertically in contact region 112. A first end of contact structure 125 can be electrically connected to a corresponding interconnect 115 or any other interconnect structure in first semiconductor structure 104. A second end of contact structure 125 can be electrically connected to a contact pad 150 through a pad-out interconnect layer (not shown). In some implementations, the pad-out interconnect layer and contact pad 150 can transfer electrical signals between 3D memory device 100 and outside circuits, e.g., for pad-out purposes.

It is understood that the relative positions of stacked first and second semiconductor structures 104 and 102 are not limited. Bonding interface 106 is formed vertically between first and second semiconductor structures 104 and 102 in 3D memory device 100, and first and second semiconductor structures 104 and 102 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between memory cell array 130 in first semiconductor structure 104 and peripheral circuits 132 in second semiconductor structure 102 can be performed through interconnects 115 (e.g., bonding contacts) across bonding interface 106.

It is noted that x, y, and z axes are included in FIG. 1A to further illustrate the spatial relationship of the components in 3D memory devices 100. The substrate of the 3D memory device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the 3D memory device is determined relative to the substrate of the 3D memory device in the z-direction (the vertical direction perpendicular to the x-y plane, e.g., the thickness direction of the substrate) when the substrate is positioned in the lowest plane of the 3D memory device in the z-direction. The same notion for describing the spatial relationships is applied throughout the present disclosure.

FIG. 1B illustrates a schematic diagram of a memory device 160 including peripheral circuits 132 and memory cell array 130 (e.g., an array of memory cells 170), according to some aspects of the present disclosure. Peripheral circuits 132 are coupled to memory cell array 130. Memory device 160 can be an example of 3D memory device 100. Memory cell array 130 can be any suitable memory cell array in which memory cell 170 includes a vertical transistor 172 and a storage unit 174 coupled to vertical transistor 172. In some implementations, memory cell array 130 is a DRAM cell array, and storage unit 174 is a capacitor for storing charge as the binary information stored by the respective DRAM cell. In some implementations, memory cell array 130 is a PCM cell array, and storage unit 174 is a PCM element (e.g., including chalcogenide alloys) for storing binary information of the respective PCM cell based on the different resistivities of the PCM element in the amorphous phase and the crystalline phase. In some implementations, memory cell array 130 is a FRAM cell array, and storage unit 174 is a ferroelectric capacitor for storing binary information of the respective FRAM cell based on the switch between two polarization states of ferroelectric materials under an external electric field.

As shown in FIG. 1B, memory cells 170 can be arranged in a two-dimensional (2D) array having rows and columns. Memory device 160 can include word lines 166 coupling to peripheral circuits 132 and memory cell array 130 for controlling the switch of vertical transistors 172 in memory cells 170 located in a row, as well as bit lines 168 coupling to peripheral circuits 132 and memory cell array 130 for sending data to and/or receiving data from memory cells 170 located in a column. That is, word line 166 is coupled to a respective row of memory cells 170, and bit line 168 is coupled to a respective column of memory cells 170.

Consistent with the scope of the present disclosure, vertical transistors 172, such as vertical metal-oxide-semiconductor field-effect transistors (MOSFETs), can replace the conventional planar transistors as the pass transistors of memory cells 170 to reduce the area occupied by the pass transistors, the coupling capacitance, as well as the interconnect routing complexity. As shown in FIG. 1B, in some implementations, different from planar transistors in which the active regions are formed in the substrates, vertical transistor 172 includes a semiconductor body 175 extending vertically (in the z-direction) above the substrate (not shown). That is, semiconductor body 175 can extend above the top surface of the substrate to expose not only the top surface of semiconductor body 175, but also one or more side surfaces thereof. As shown in FIG. 1A, for example, semiconductor body 175 can have a cuboid shape to expose four sides thereof. It is understood that semiconductor body 175 may have any suitable 3D shape, such as a polyhedron shape or a cylinder shape. That is, the cross section of semiconductor body 175 in the plan view (e.g., in the x-y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered to having multiple sides, such that the gate structures are in contact with more than one side of the semiconductor bodies. Semiconductor body 175 can be formed from the substrate (e.g., by etching or epitaxy) and thus, has the same semiconductor material (e.g., crystalline silicon) as the substrate (e.g., a silicon substrate).

In some implementations, vertical transistor 172 can also include a gate structure 178 in contact with one or more sides of semiconductor body 175, i.e., in one or more planes of the side surface(s) of the active region. In other words, the active region of vertical transistor 172, i.e., semiconductor body 175, can be at least partially surrounded by gate structure 178. It is noted that, FIG. 1B shows that gate structure 178 can be an all-around-gate structure laterally surrounding all sides of semiconductor body 175. In some other implementations not shown in FIG. 1B, gate structure 178 can include one or more flat sides or curved sides partially surrounding semiconductor body 175.

Gate structure 178 can include a gate dielectric layer 177 over one or more sides of semiconductor body 175, e.g., in contact with four side surfaces of semiconductor body 175, as shown in FIG. 1B. Gate structure 178 can also include a gate electrode 176 over and in contact with gate dielectric layer 177. Gate dielectric layer 177 can include any suitable dielectric materials, such as silicon oxide, silicon nitride, silicon oxynitride, or high-k dielectrics. For example, gate dielectric layer 177 may include silicon oxide, i.e., gate oxide. Gate electrode 176 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 176 may include doped polysilicon, i.e., a gate poly. In some implementations, gate electrode 176 includes multiple conductive layers, such as a W layer over a TiN layer. It is understood that gate electrode 176 and word line 166 may be a continuous conductive structure in some examples. In other words, gate electrode 176 may be viewed as part of word line 166 that forms gate structure 178, or word line 166 may be viewed as the extension of gate electrode 176 to be coupled to peripheral circuits 132.

As shown in FIG. 1B, vertical transistor 172 can further include a pair of a source and a drain (S/D, doped regions, a.k.a., source electrode and drain electrode) formed at the two ends of semiconductor body 175 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 178 in the vertical direction (the z-direction). In other words, gate structure 178 is formed vertically between the source and drain. As a result, one or more channels (not shown) of vertical transistor 172 can be formed in semiconductor body 175 vertically between the source and drain when a gate voltage applied to gate electrode 176 of gate structure 178 is above the threshold voltage of vertical transistor 172. That is, the channel of vertical transistor 172 is also formed in the vertical direction along which semiconductor body 175 extends, according to some implementations.

In some implementations, as shown in FIG. 1B, vertical transistor 172 is a multi-gate transistor. That is, gate structure 178 can be in contact with more than one side of semiconductor body 175 (e.g., four sides in FIG. 1B) to form more than one gate, such that more than one channel can be formed between the source and drain in operation. It is understood that vertical transistors 172 disclosed herein may also include single-gate transistors. That is, gate structure 178 may be in contact with a single side of semiconductor body 175, for example, for the purpose of increasing the transistor and memory cell density. It is also understood that although gate dielectric layer 177 is shown as being separate (i.e., a separate structure) from other gate dielectrics of adjacent vertical transistors (not shown), gate dielectric layer 177 may be part of a continuous dielectric layer having multiple gate dielectric layers of vertical transistors 172.

In vertical transistor 172, semiconductor body 175 extends vertically (in the z-direction), and the source and the drain are disposed in the different lateral planes, according to some implementations. In some implementations, the source and the drain are formed at two ends of semiconductor body 175 in the vertical direction (the z-direction), respectively, thereby overlapping in the plan view. As a result, the area (in the x-y plane) occupied by vertical transistor 172 can be reduced compared with planar transistors and lateral multiple-gate transistors. Also, the metal wiring coupled to vertical transistors 172 can be simplified as well since the interconnects can be routed in different planes. For example, bit lines 168 and storage units 174 may be formed on opposite sides of vertical transistor 172. In one example, bit line 168 may be coupled to the source or the drain at the upper end of semiconductor body 175, while storage unit 174 may be coupled to the other source or the drain at the lower end of semiconductor body 175.

As shown in FIG. 1B, storage unit 174 can be coupled to the source or the drain of vertical transistor 172. Storage units 174 can include any devices that are capable of storing binary data (e.g., 0 and 1), including but not limited to, capacitors for DRAM cells and FRAM cells, and PCM elements for PCM cells. In some implementations, vertical transistor 172 controls the selection and/or the state switch of the respective storage unit 174 coupled to vertical transistor 172. In some implementations as shown in FIG. 1B, memory cell 170 is a DRAM cell including vertical transistor 172 and a capacitor (e.g., an example of storage unit 174 in FIG. 1B). In some implementations, the capacitor is a vertical compactor. An example structure of the vertical capacitor is described below in more detail with reference to FIGS. 4A and 4C.

Peripheral circuits 132 can be coupled to memory cell array 130 through bit lines 168, word lines 166, and any other suitable metal wirings. As described above, peripheral circuits 132 can include any suitable circuits for facilitating the operations of memory cell array 130 by applying and sensing voltage signals and/or current signals through word lines 166 and bit lines 168 to and from memory cell 170.

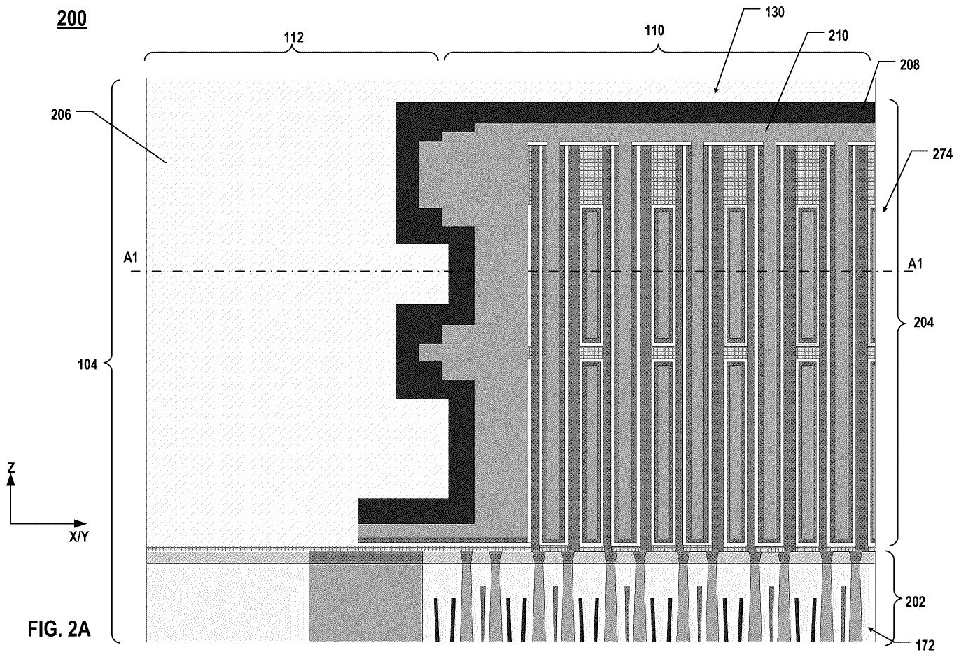

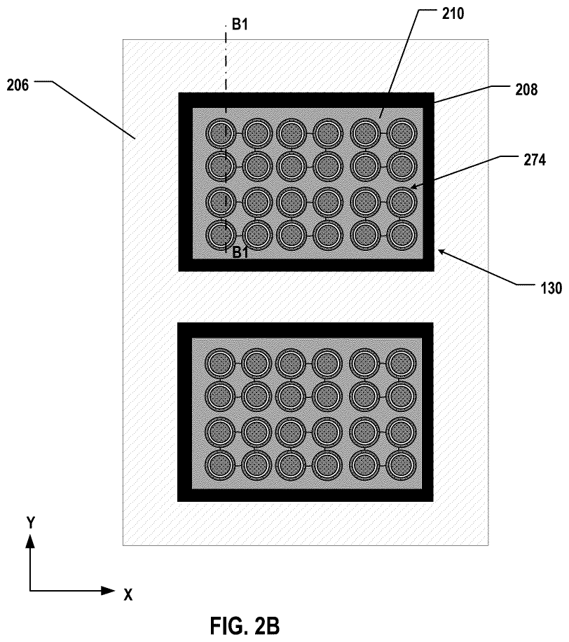

FIG. 2A illustrates a side view of a cross section of a memory device 200, according to some examples of the present disclosure. FIG. 2B illustrates a plan view of a cross section of memory device 200, according to some examples of the present disclosure. The cross section of memory device 200 in FIG. 2B may be along a line A1-A1 in FIG. 2A. The cross section of memory device 200 in FIG. 2A may be along a line B1-B1 in FIG. 2B. FIGS. 2A and 2B are described together.

Memory device 200 may be an example of 3D memory device 100 of FIG. 1A. As shown in FIG. 2A, memory device 200 may include first semiconductor structure 104. First semiconductor structure 104 includes a transistor structure 202 and a storage structure 204 stacked over transistor structure 202. Transistor structure 202 may include an array of transistors (e.g., an array of vertical transistors 172). Storage structure 204 may include memory cell array 130 in memory array region 110. Memory cell array 130 may include an array of vertical capacitors 274 which includes a GeSi layer 210. A W layer 208 may cover GeSi layer 210. Storage structure 204 may further include a dielectric structure 206, which is formed by filling contact region 112 with a dielectric material (e.g., silicon oxide). A part of dielectric structure 206 may be formed on top of W layer 208 to cover W layer 208. As shown in FIG. 2B, memory cell arrays 130 in memory device 200 are separated and isolated by dielectric structure 206.

FIGS. 3A-3M illustrate a fabrication process for forming memory device 200, according to some examples of the present disclosure. Referring to FIGS. 3A and 3B (e.g., FIG. 3B is a plan view of the structure of FIG. 3A), transistor structure 202 including an array of vertical transistors 172 is formed. A stack structure 302 is formed on transistor structure 202. Stack structure 302 may be formed by depositing alternating first layers 304 (304A, 304B, 304C) and first dielectric layers 306 (306A, 306B) on transistor structure 202 across memory array region 110 and contact region 112, using one or more thin film deposition processes including, but not limited to, chemical vapor deposition (CVD), physical vapor deposition (PVD), atomic layer deposition (ALD), or any combination thereof. First dielectric layers 306 may include the same dielectric material, whereas first layers 304 may include the same dielectric material or different dielectric materials. The dielectric material(s) of first layers 304 may be different from the dielectric material of first dielectric layers 306. For example, first dielectric layers 306A and 306B may include silicon oxide. First layer 304A may include silicon nitride (SiN) or silicon boron nitride (SiBN). First layer 304B may include silicon carbon nitride (SiCN). First layer 304C may include SiN or SiCN.

Hard masks 308 and 310 may be formed on top of stack structure 302. Hard mask 308 may include polysilicon, whereas hard mask 310 may include silicon oxide. Hard mask 310 may be etched to form openings 312 in memory array region 110. In some implementations, fabrication processes for forming openings 312 include wet etching and/or dry etching, such as deep-ion reactive etching (DRIE).

Referring to FIG. 3C, hard mask 308 may be etched to form openings 314 through openings 312 of hard mask 310 of FIG. 3A in memory array region 110. In some implementations, fabrication processes for forming openings 314 include wet etching and/or dry etching, such as DRIE. Then, hard mask 310 of FIG. 3A which covers hard mask 308 may be removed.

Referring to FIG. 3D, stack structure 302 may be etched to from storage openings 316, which extend through stack structure 302 in memory array region 110. In some implementations, fabrication processes for forming storage openings 316 include wet etching and/or dry etching, such as DRIE. Then, hard mask 308 of FIG. 3C which covers stack structure 302 may be removed.

Referring to FIG. 3E, first electrode structures 318 of vertical capacitors 274 are formed in storage openings 316 of FIG. 3D. First electrode structures 318 may be formed by depositing one or more conductive layers into storage openings 316 using one or more thin film deposition processes such as CVD, PVD, ALD, or any combination thereof. For example, first electrode structures 318 may be formed by filling storage openings 316 with titanium nitride (TiN). First electrode structure 318 may be coupled to a respective vertical transistor 172 in transistor structure 202.

Referring to FIGS. 3F and 3G (e.g., FIG. 3G is a plan view of the structure of FIG. 3F), a mesh hard mask 320 can be deposited on top of stack structure 302 of FIG. 3E. A photoresist layer 321 can be deposited on top of mesh hard mask 320. Photoresist layer 321 may be patterned to form openings 322 to expose mesh hard mask 320 through openings 322 in memory array region 110. A part of photoresist layer 321 in contact region 112 may also be removed to expose mesh hard mask 320 in contact region 112. Portions of mesh hard mask 320 exposed by photoresist layer 321 may be etched to expose first layer 304C, such that the exposed portions of first layer 304C can be etched away as shown in FIG. 3H below.

Referring to FIGS. 3H and 3I (e.g., FIG. 3I is a plan view of the structure of FIG. 3H), first layer 304C may be etched to form mesh openings 324 in memory array region 110 through openings 322 in mesh hard mask 320 of FIG. 3F. The part of mesh hard mask 320 in contact region 112 and the part of first layer 304C in contact region 112 are completely removed. Then, the entire first dielectric layer 306B between first layer 304C and first layer 304B (shown in FIG. 3F) is removed using wet etching and/or dry etching, such as DRIE.

Referring to FIG. 3J, first layer 304B may be etched to form mesh openings 326 in memory array region 110 through openings 322 in mesh hard mask 320 and meshing openings 324. The part of first layer 304B in contact region 112 is completely removed. Then, the entire first dielectric layer 306A between first layer 304B and first layer 304A (shown in FIG. 3H) is removed using wet etching and/or dry etching, such as DRIE.

Referring to FIG. 3K, second electrode structures corresponding to vertical capacitors 274 may be formed in memory array region 110 by depositing a high dielectric constant (high-k) dielectric layer 328 to cover first electrode structures 318 and one or more conductive layers over the high-k dielectric layer (e.g., a TiN layer 329 and GeSi layer 210 over high-k dielectric layer 328, and W layer 208 over GeSi layer 210). High-k dielectric layer 328, TiN layer 329, GeSi layer 210, and W layer 208 may also extend across contact region 112 and memory array region 110.

Referring to FIG. 3L, a part of high-k dielectric layer 328, a part of TiN layer 329, a part of GeSi layer 210, and a part of W layer 208 in contact region 112 may be etched away. Referring to FIG. 3M, dielectric structure 206 may be formed by filling contact region 112 with a dielectric material (e.g., silicon oxide). Dielectric structure 206 may also cover W layer 208 in memory array region 110 as shown in FIG. 3M.

As shown in FIGS. 3H-3J above, to form dielectric structure 206, a part of stack structure 302 in contact region 112 needs to be completely removed. This removal of stack structure 302 in contact region 112, as well as the refilling of a dielectric material in contact region 112 to form dielectric structure 206, may result in a high manufacturing cost. Additionally, lateral width 330 (shown in FIG. 3J) for removing stack structure 302 in contact region 112 is large, which may result in waste in the space between the memory cell arrays.

FIG. 4A illustrates a side view of cross sections of a memory device 400, according to some aspects of the present disclosure. FIG. 4B illustrates a plan view of a cross section of memory device 400, according to some aspects of the present disclosure. The cross sections of FIG. 4A are along a line B2-B2 and a line C-C of FIG. 4B, whereas the cross section of FIG. 4B is along a line A2-A2 of FIG. 4A. FIGS. 4A and 4B are described together. It is understood that FIGS. 4A and 4B are for illustrative purposes only and may not necessarily reflect the actual device structure (e.g., interconnections) in practice.

Memory device 400 can be a DRAM memory device including an array of DRAM cells. As shown in FIG. 4A, memory device 400 can include first semiconductor structure 104, which includes transistor structure 202 and storage structure 204. In some implementations, transistor structure 202 includes an array of vertical transistors 172, and storage structure 204 includes an array of vertical capacitors 274 in memory array region 110. That is, the DRAM cell can include a vertical capacitor 274 and a vertical transistor 172 coupled with vertical capacitor 274. In some implementations, an array of source node contact (SNC) structures 480 are coupled between the array of vertical transistors 172 and the array of vertical capacitors 274. In some examples, the array of vertical transistors 172 and the array of vertical capacitors 274 may form a memory cell array 130 in memory array region 110.

In some implementations, vertical transistor 172 (e.g., a MOSFET) may be configured to switch a respective DRAM cell. Vertical transistor 172 includes semiconductor body 175 (i.e., the active region in which multiple channels can form) extending vertically (in the z-direction), and a gate structure located at one or more lateral sides of semiconductor body 175. In some implementations, semiconductor body 175 can include any suitable semiconductor material, such as monocrystalline silicon, polycrystalline silicon, or silicon-germanium. In some other implementations, the leakage value of the semiconductor body 175 is lower than a pico-ampere. For example, semiconductor body 175 can include a metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc. In some implementations, adjacent semiconductor bodies 175 can be laterally separated from each other by an isolation member 423 including isolation oxides (TISO) and/or air gaps.

In some implementations, semiconductor body 175 extends in a vertical direction (the z-direction), and includes a source and a drain disposed at the two ends (the upper end and lower end) of semiconductor body 175, respectively. Source and drain can be doped with N-type dopants (e.g., P or As) or P-type dopants (e.g., B or Ga) at a desired doping level. In some implementations, the source is coupled to vertical capacitor 274 through SNC structure 480, and the drain is coupled to a bit line (not shown). In some implementations, the sources of adjacent semiconductor bodies 175 can be laterally separated from each other by an insulating layer 439 including any suitable dielectric material (e.g., silicon oxide). In some implementations, the drains of semiconductor bodies 175 of a column of DRAM cells along the bit line direction (i.e., the y-direction) can be laterally connected with each other to form a common drain that is coupled to a common bit line (not shown), which extends in the bit line direction (the y-direction).

In some implementations, the gate structure of vertical transistor 172 includes a gate dielectric and a gate electrode 176. In some implementations, the gate dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 176 includes conductive materials including, but not limited to, W, Co, Cu, Al, TiN, TaN, polysilicon, silicide, or any combination thereof. In some implementations, gate electrode 176 includes multiple conductive layers, such as a W layer over a TiN layer. In one example, the gate structure may be a “gate oxide/gate poly” gate in which the gate dielectric includes silicon oxide, and the gate electrode 176 includes doped polysilicon. In another example, the gate structure may be a high-k metal gate (HKMG) in which the gate dielectric includes a high-k dielectric, and the gate electrode 176 includes a metal. In some implementations, the gate structures of adjacent semiconductor bodies 175 can be laterally separated from each other by insulating layer 439.

In some implementations, gate electrode 176 may be part of a word line or extend in the word line direction (the x-direction) as a word line. The word line can extend in the word line direction (the x-direction), and be coupled to a row of DRAM cells. That is, the bit line and the word line can extend in two perpendicular lateral directions, and semiconductor body 175 of vertical transistor 172 can extend in the vertical direction perpendicular to the two lateral directions in which the bit line and the word line extend.

In some implementations, SNC structure 480 may include a conductive layer in contact with a corresponding vertical capacitor 274. In some implementations, the conductive layer can include any suitable conductive materials, such as polysilicon, Al, Cu, W, etc.

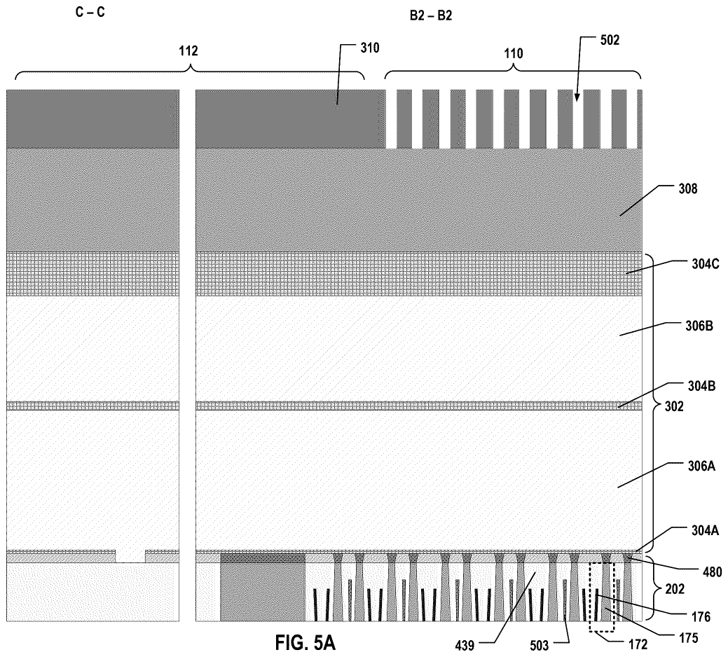

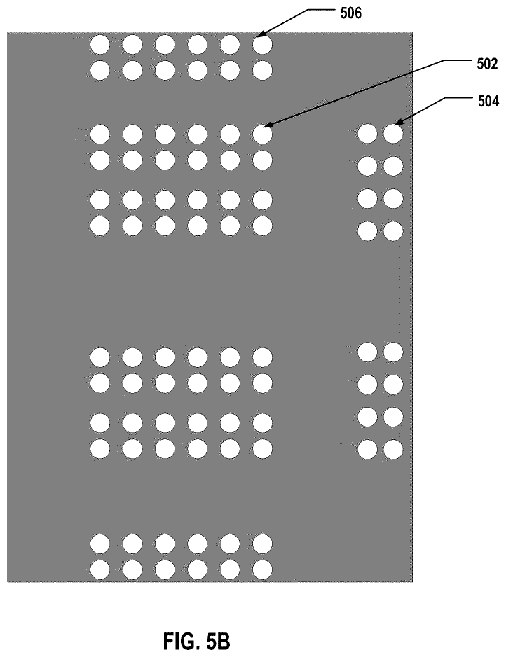

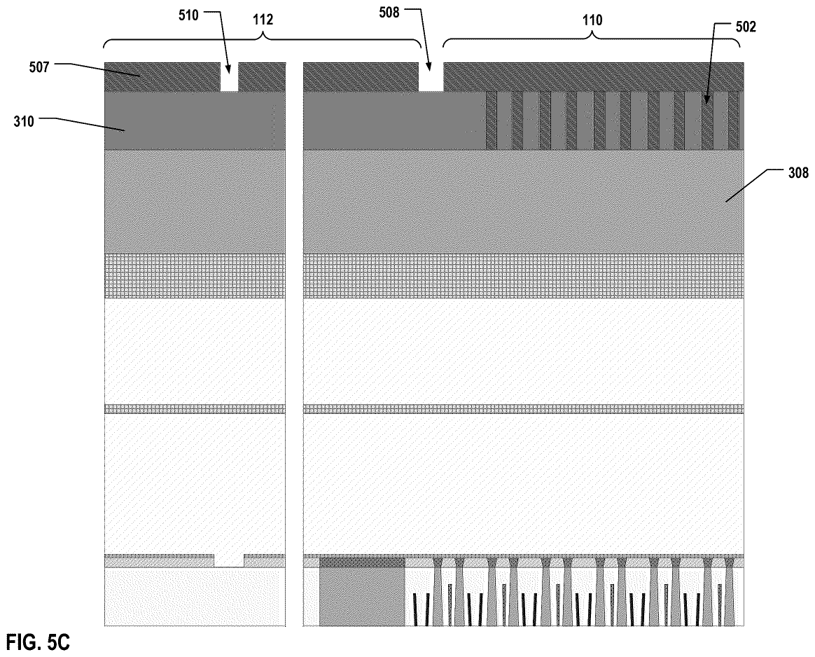

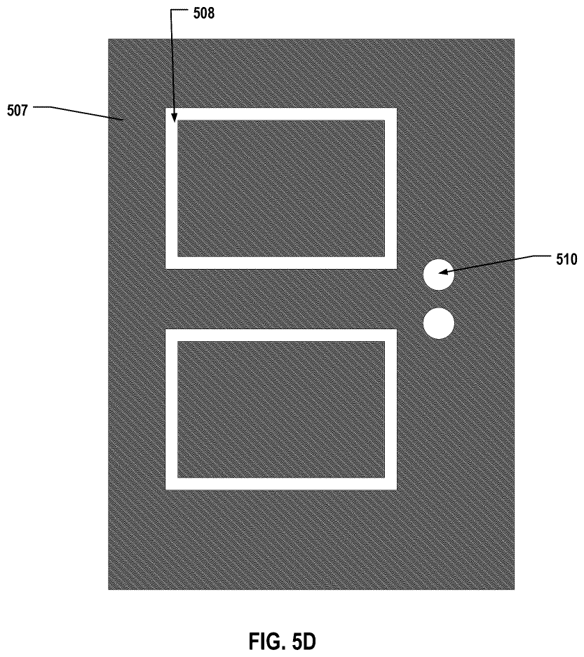

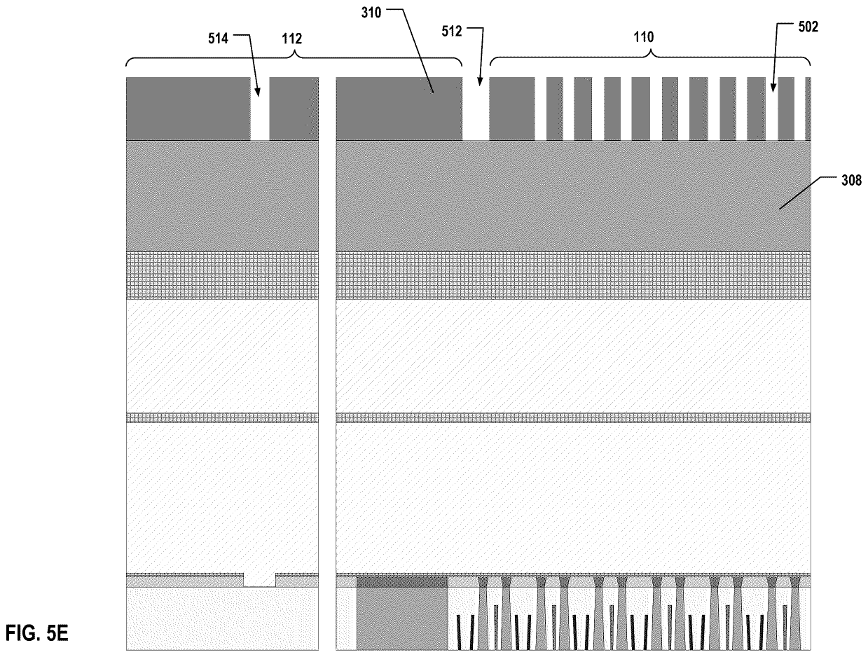

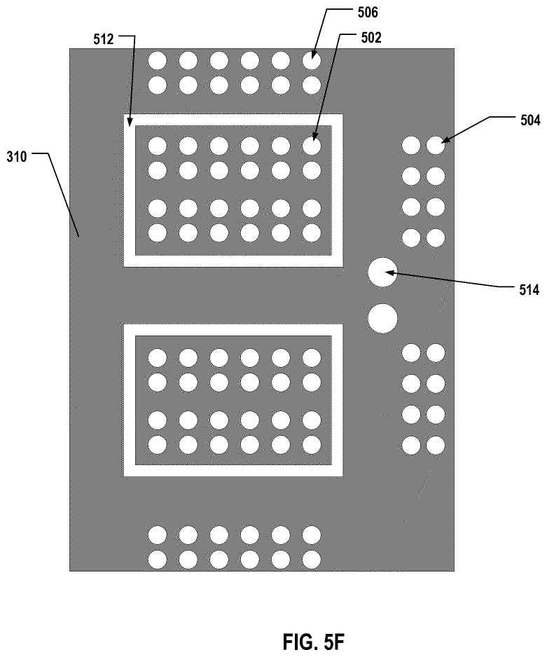

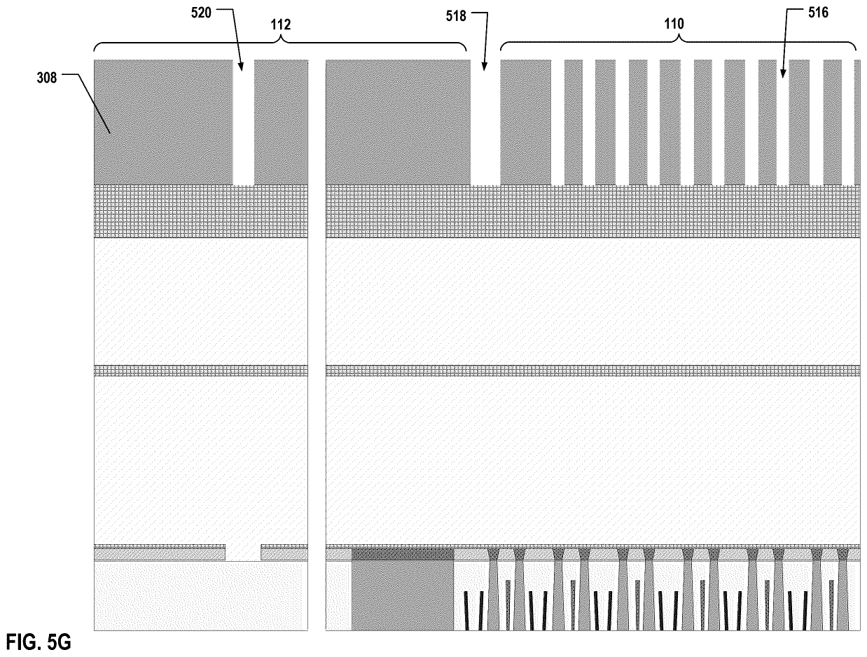

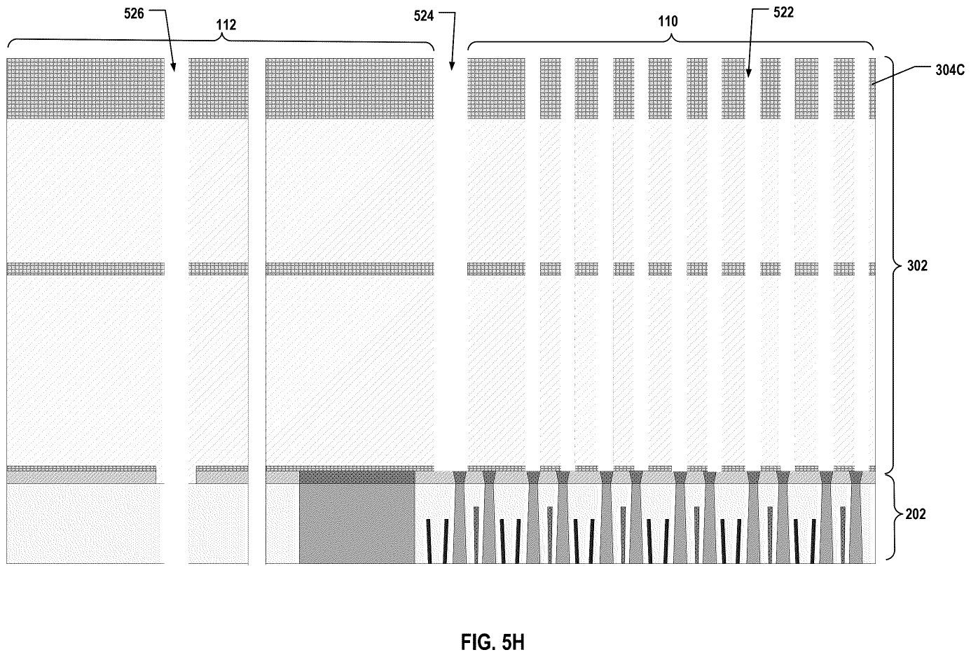

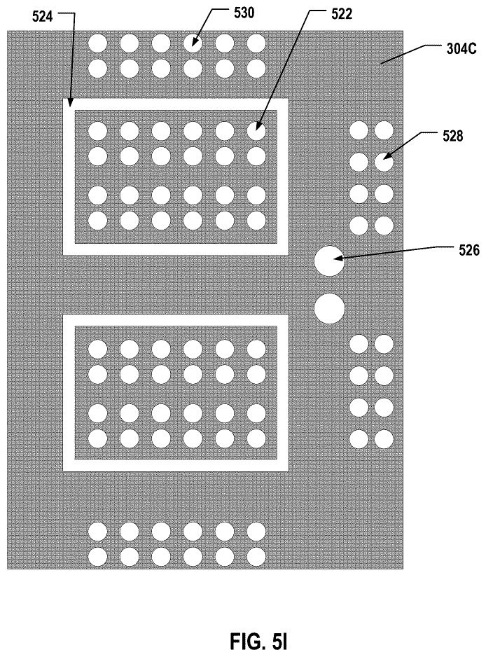

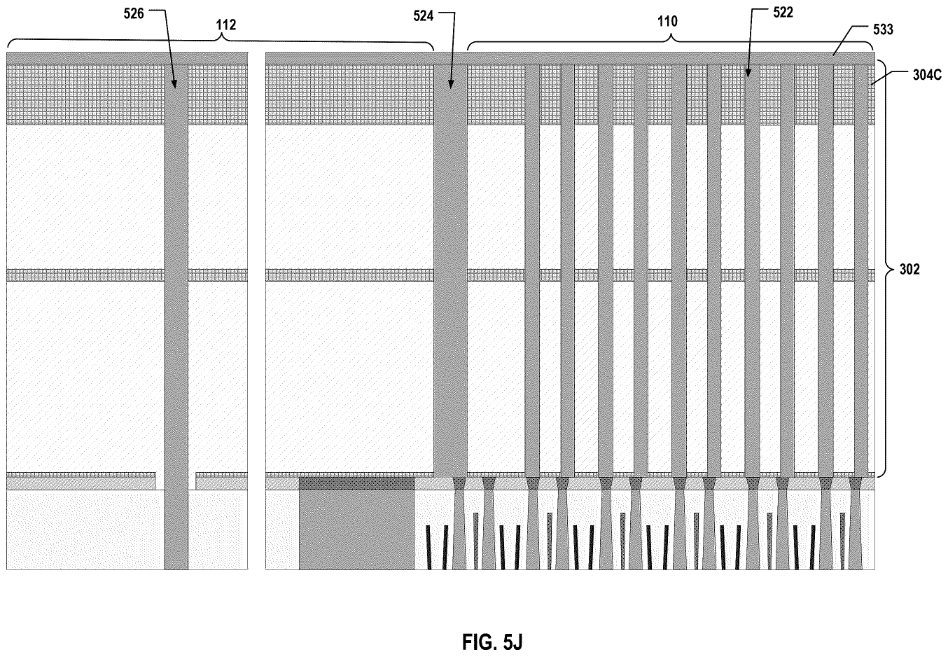

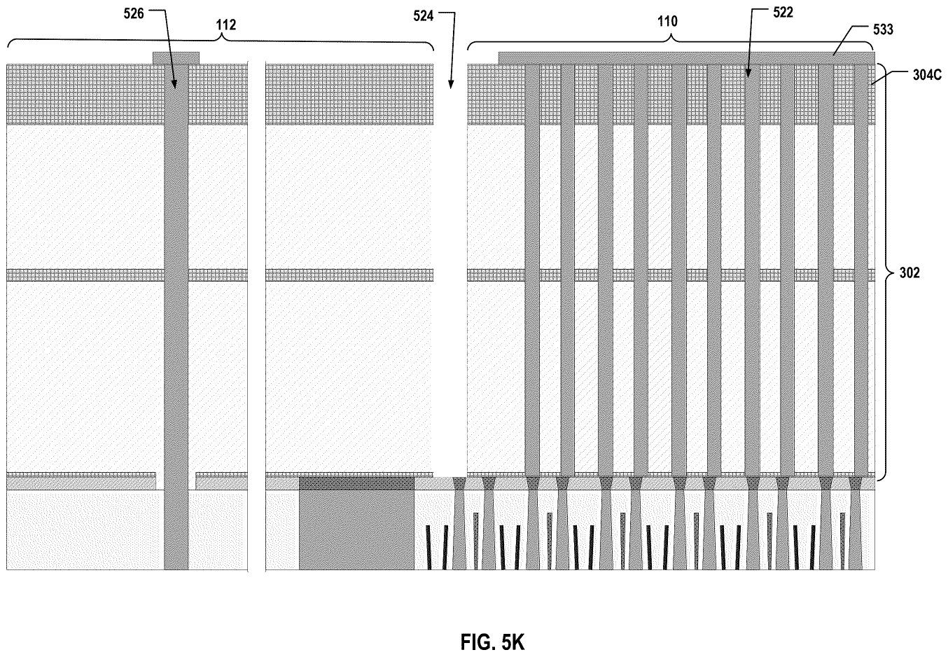

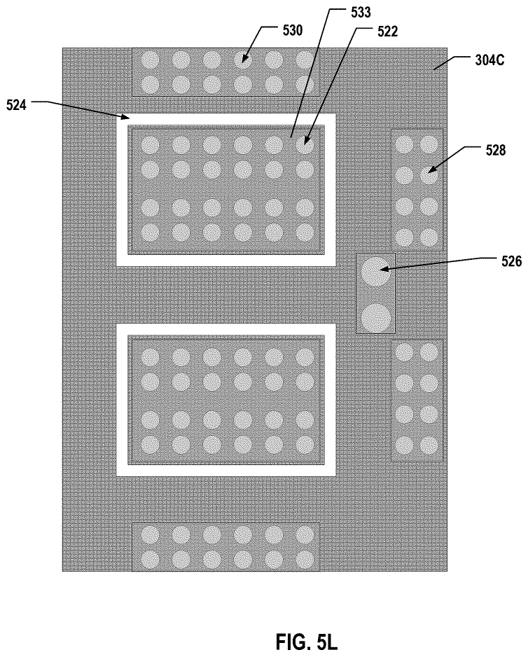

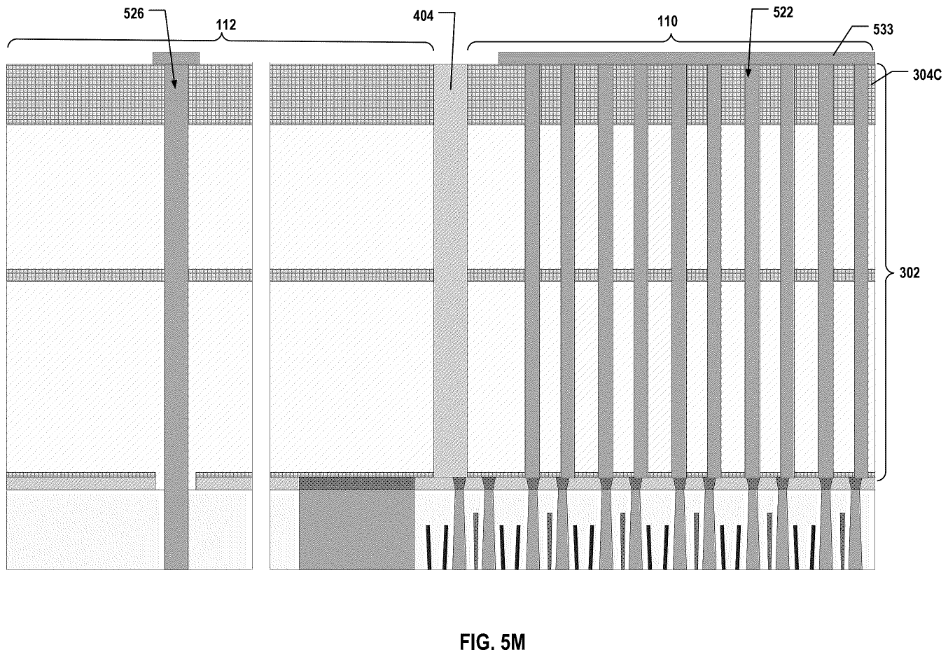

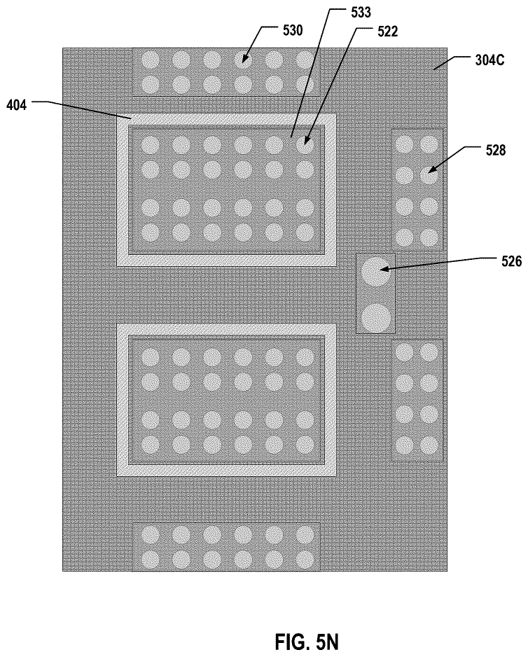

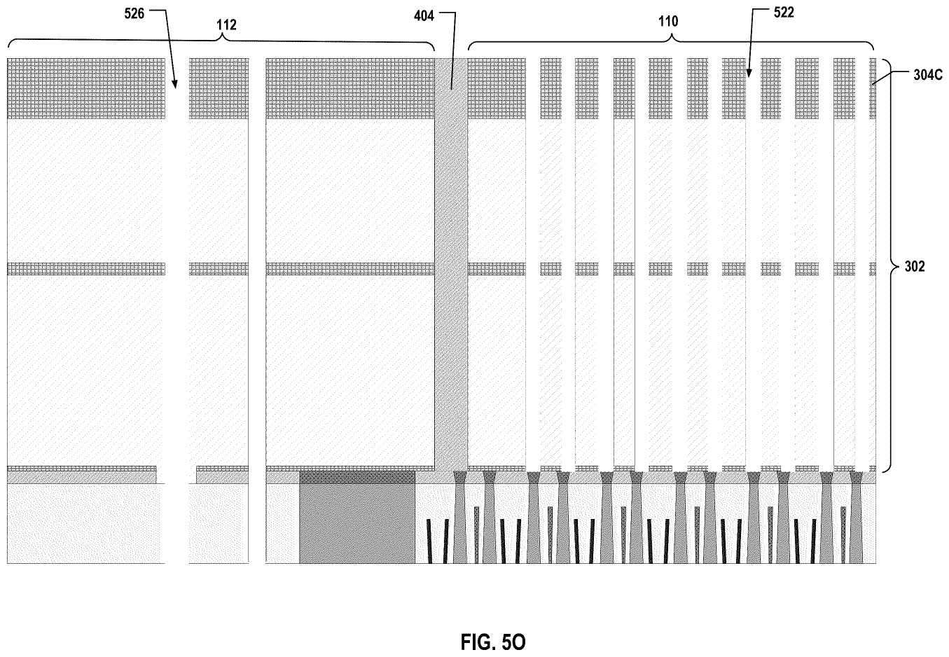

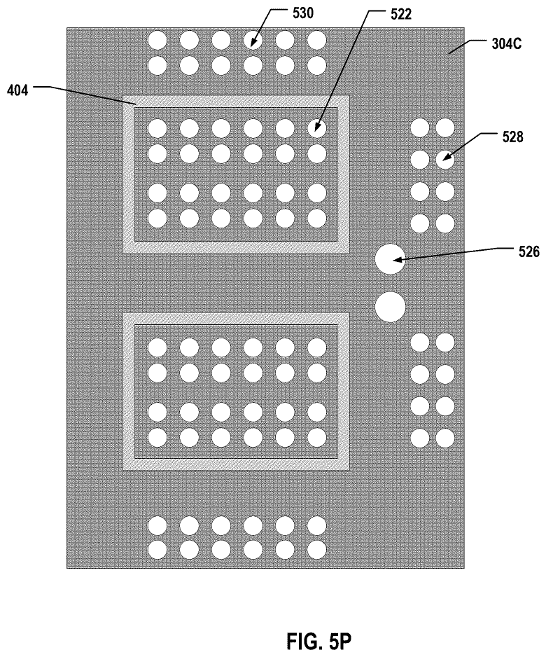

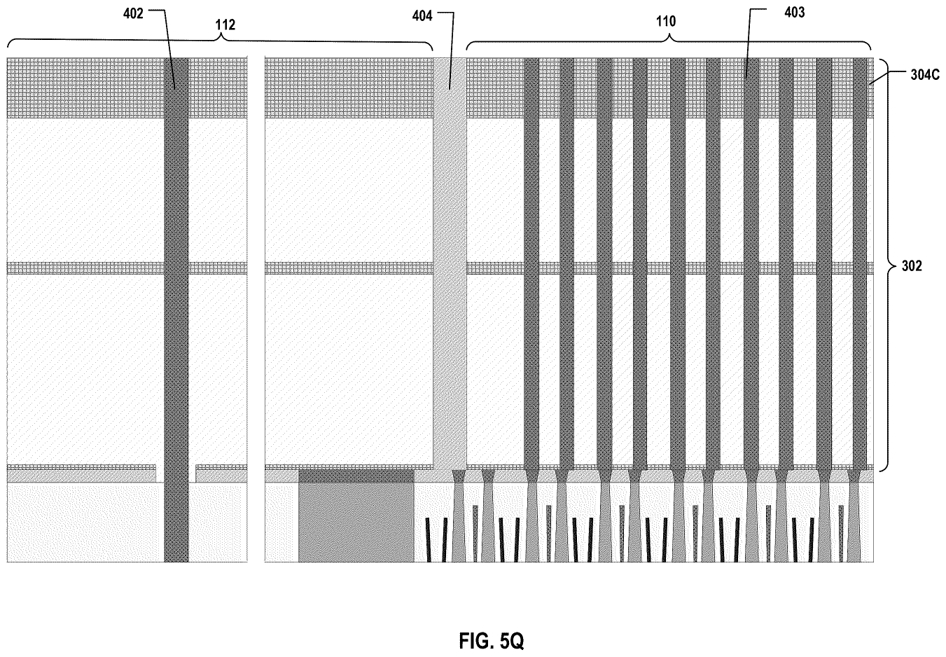

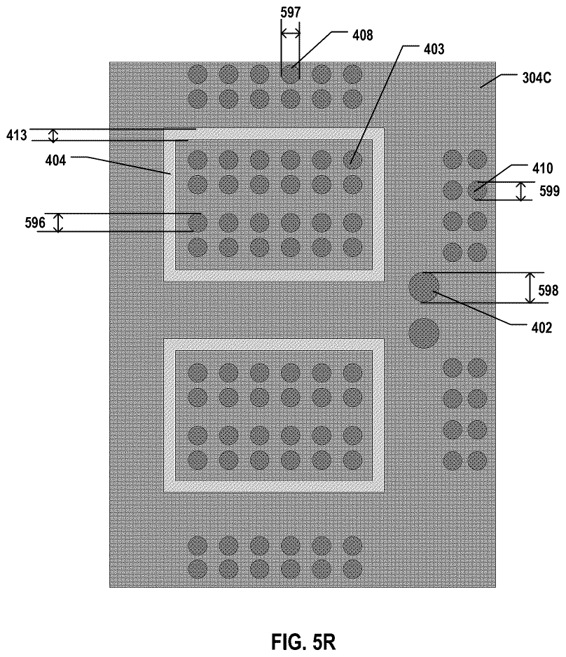

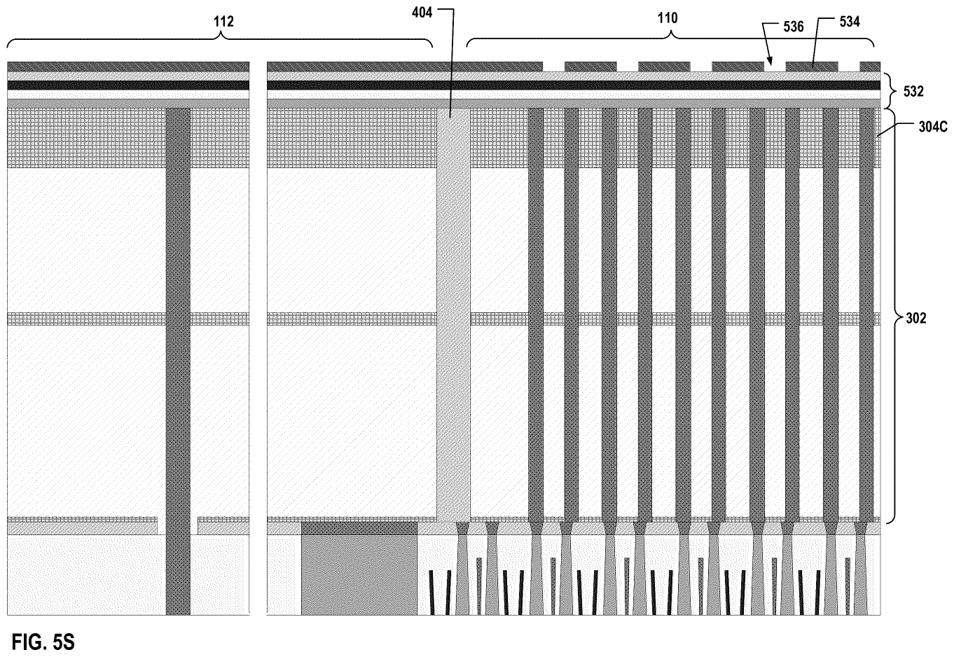

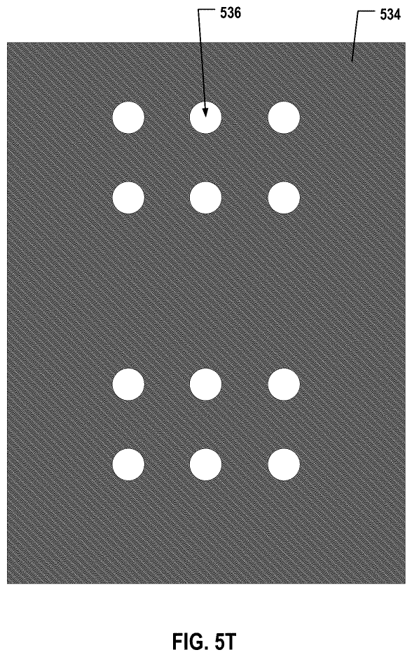

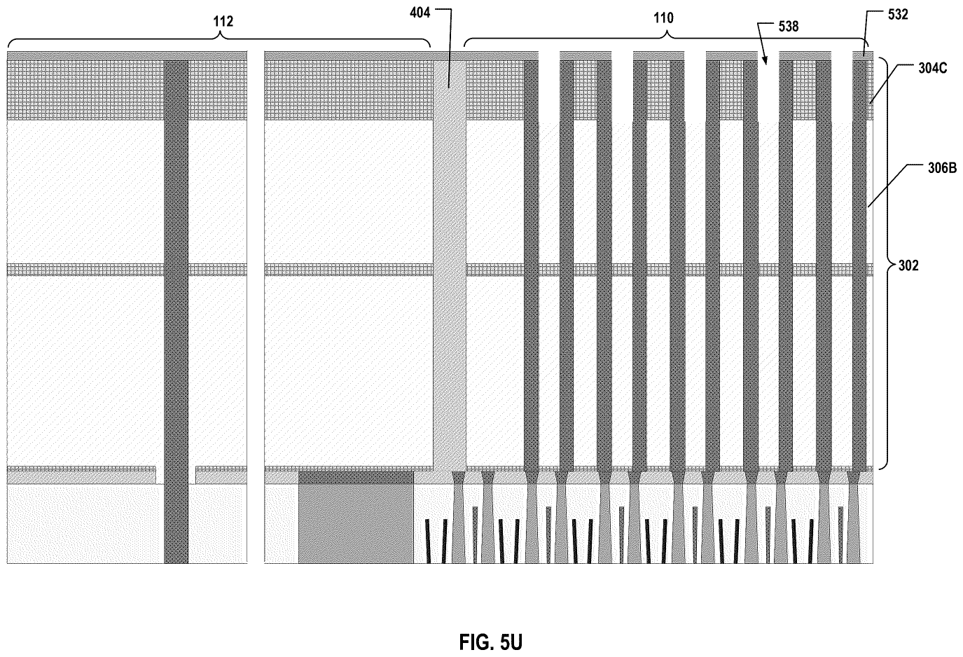

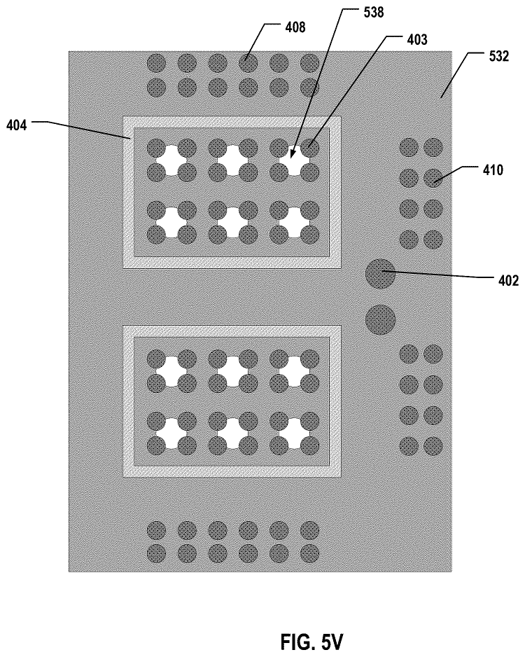

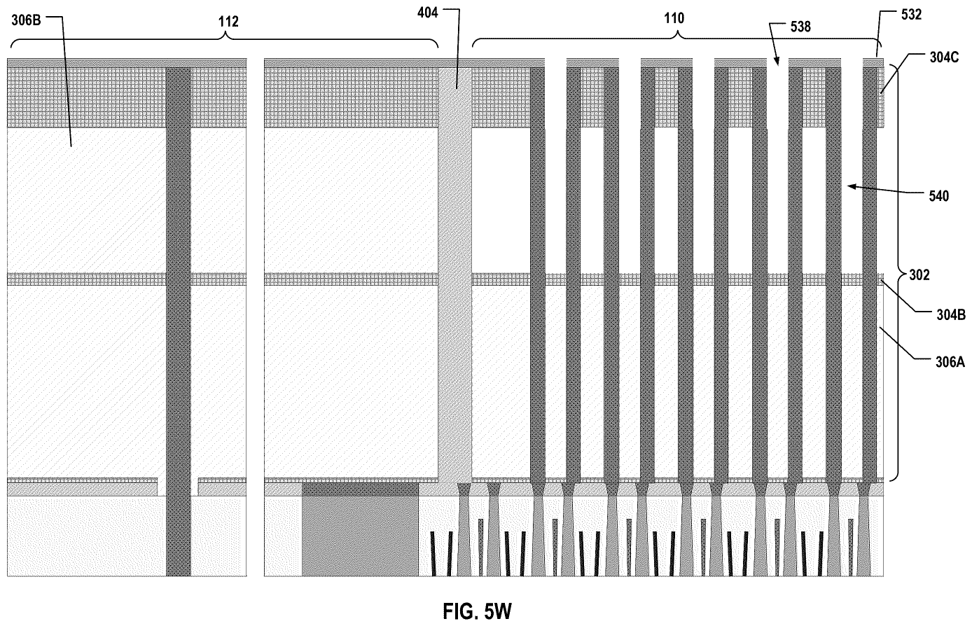

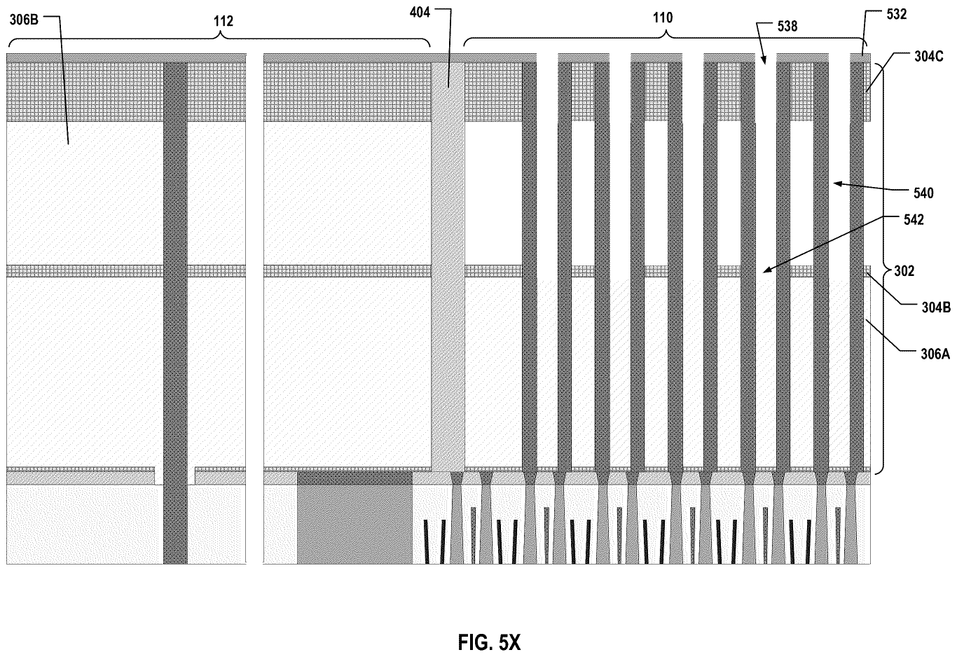

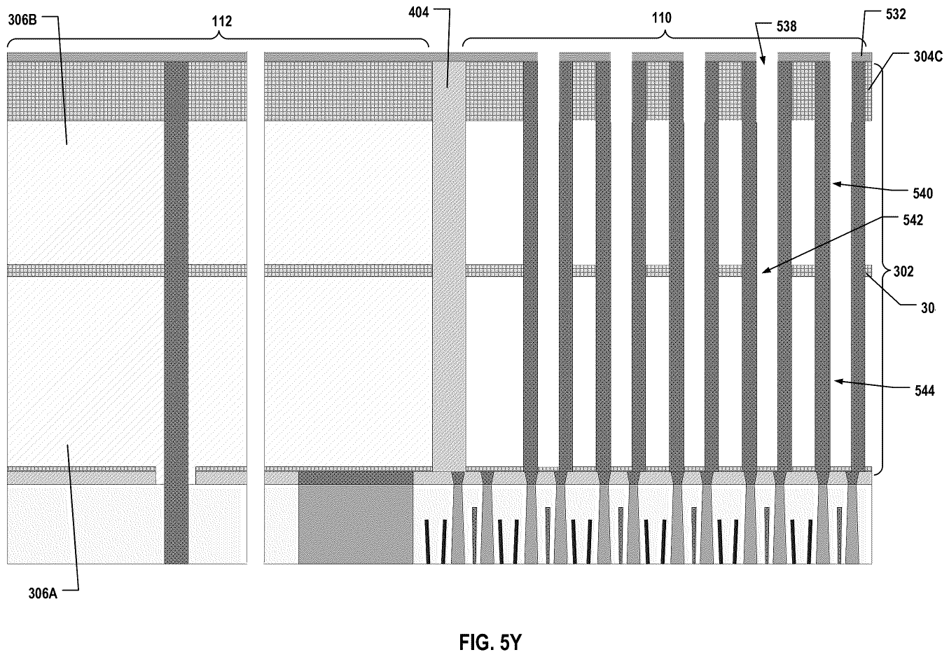

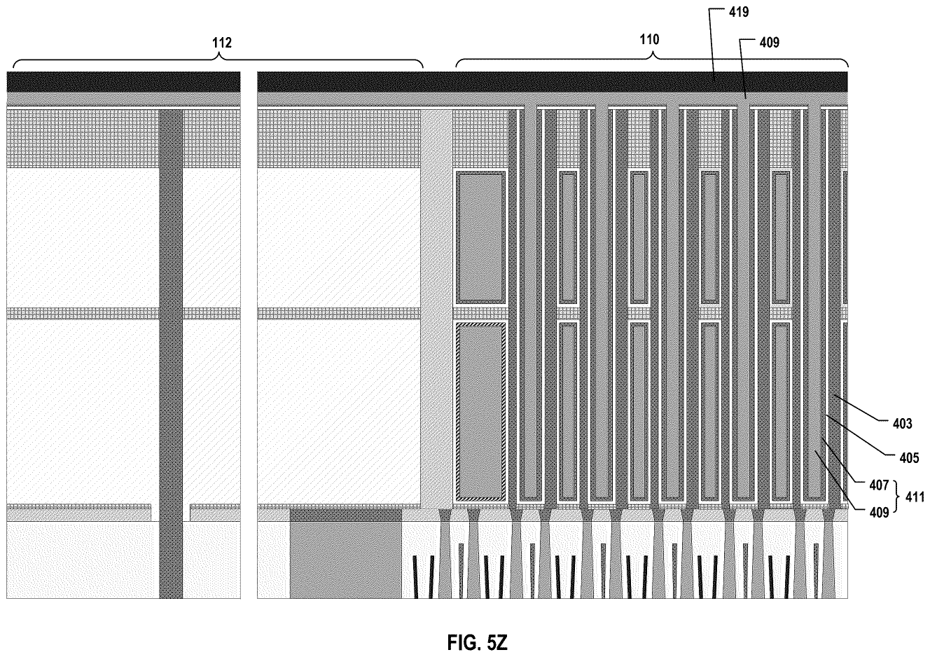

Vertical capacitor 274 can include a first electrode structure 403, a second electrode structure 411 (shown in FIG. 4C), and a storage dielectric layer 405 formed between first electrode structure 403 and second electrode structure 411. An enlarged view of vertical capacitor 274 is shown in FIG. 4C, where a dashed circle 493 illustrates a projection of a mesh opening 538 of FIG. 5U onto the cross section of FIG. 4B. Four vertical capacitors 274 are formed around the projection of mesh opening 538. Referring to FIG. 4A, first electrode structure 403 can have a cylinder shape structure fixed in first layers 304A, 304B, and 304C. First and second electrode structures 403 and 411, as well as storage dielectric layer 405, extend vertically (in the z-direction), and storage dielectric layer 405 can be sandwiched between first and second electrode structures 403 and 411. In some implementations, second electrode structures 411 are connected with each other and function as a common electrode, while first electrode structure 403 is coupled to a source of a respective vertical transistor 172 in the same DRAM cell through SNC structure 480.

In some implementations, first electrode structure 403 and/or second electrode structure 411 can include conductive materials including, but not limited to, W, Co, Cu, Al, TiN, TaN, polysilicon, silicide, or any combination thereof. In some implementations, first electrode structure 403 and/or second electrode structure 411 can include a single-layer structure or a multi-layer structure, with a layer of the multi-layer structure including one of TiN, TaN, carbon, polysilicon, metal, metal compounds, or silicide. For example, first electrode structure 403 can include a TiN layer or another suitable conductive layer. Alternatively, first electrode structure 403 can include a polysilicon layer and a TiN layer. Second electrode structure 411 can include a first conductive layer 407 (e.g., a TiN layer) and a second conductive layer 409 (e.g., a GeSi layer). A third conductive layer 419 (e.g., a W layer) may be deposited on second conductive layer 409. In some implementations, storage dielectric layer 405 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof.

As illustrated in FIGS. 4A-4B, memory device 400 may further include stack structure 302 in contact region 112 and an isolation structure 404 located between memory array region 110 and contact region 112. Isolation structure 404 may isolate the array of vertical capacitors 274 in memory array region 110 from stack structure 302 in contact region 112. Isolation structure 404 may include a dielectric material including, but not limited to, silicon nitride, silicon oxynitride, silicon carbon nitride (SiCN), silicon boron nitride (SiBN), or any combination thereof. The dielectric material of isolation structure 404 may be different from that of first dielectric layers 306. As shown in FIG. 4B, isolation structure 404 may surround memory cell array 130.

Stack structure 302 may include alternating first layers 304 (e.g., 304A, 304B, 304C) and first dielectric layers 306 (e.g., 306A, 306B) in contact region 112. In some implementations, first dielectric layers 306 may include a first dielectric material, and first layers 304 may include second dielectric layers that include a second dielectric material. That is, first layers 304 are formed by the same second dielectric material. The first dielectric material may include, but is not limited to, silicon oxide, silicon nitride, silicon oxynitride, or any combination thereof. The second dielectric material may include, but is not limited to, silicon nitride, silicon oxynitride, silicon carbon nitride (SiCN), or silicon boron nitride (SiBN), or any combination thereof. The first dielectric material is different from the second dielectric material. For example, the first dielectric material may include silicon oxide. The second dielectric material may include silicon nitride, SiCN, or SiBN.

In some implementations, first dielectric layers 306 may include the first dielectric material. First layers 304 may include at least (1) a second dielectric layer that includes a second dielectric material and (2) a third dielectric layer that includes a third dielectric material. The third dielectric material may include, but is not limited to, silicon nitride, silicon oxynitride, SiCN, SiBN, or any combination thereof. The third dielectric material is different from the first dielectric material and the second dielectric material. That is, different first layers 304 may be formed by different dielectric materials. For example, the first dielectric material may include silicon oxide. The second dielectric material may include one of silicon nitride, SiCN, or SiBN, whereas the third dielectric material may include another one of silicon nitride, SiCN, or SiBN.

In one example, first dielectric layers 306A and 306B may include silicon oxide. First layer 304A may include silicon nitride or SiBN. First layer 304B may include SiCN. First layer 304C may include silicon nitride or SiCN.

As illustrated in FIGS. 4A-4B, first semiconductor structure 104 may further include a first contact structure 402 extending through stack structure 302 in contact region 112 in the vertical direction (e.g., the z direction). An end surface of first contact structure 402 that is on a first one of first layers 304 (e.g., first layer 304C) is flush with an end surface of isolation structure 404 that is on the first one of first layers 304 (e.g., first layer 304C). For example, a surface of a top end of first contact structure 402 on first layer 304C is flush with a surface of a top end of isolation structure 404. In some implementations, an opening is provided in first layer 304A (e.g., a SiBN layer), such that first contact structure 402 may not only extend through stack structure 302 but also extend through transistor structure 202 to connect with peripheral circuit 132 as shown in FIG. 4D. In some other implementations, no opening is provided in first layer 304A, such that first contact structure 402 only extends into or through stack structure 302 (e.g., first contact structure 402 does not extend into transistor structure 202).

In some implementations, first contact structure 402 can include a conductive material including, but not limited to, W, Co, Cu, Al, TiN, TaN, polysilicon, silicide, or any combination thereof. In some implementations, first contact structure 402 can include a single-layer structure or a multi-layer structure, with a layer of the multi-layer structure including one of TiN, TaN, carbon, polysilicon, metal, metal compounds, or silicide. For example, first contact structure 402 can include a TiN layer or another suitable metal layer. Alternatively, first contact structure 402 can include a polysilicon layer and a TiN layer.

With reference to FIG. 4B, first semiconductor structure 104 may further include a second contact structure 410 extending through stack structure 302 in contact region 112 in the vertical direction and coupled to a word line (e.g., word line 166 of FIG. 1B). First semiconductor structure 104 may also include a third contact structure 408 extending through stack structure 302 in contact region 112 in the vertical direction and coupled to a bit line (e.g., bit line 168 of FIG. 1B). It is contemplated that first semiconductor structure 104 may also include dummy contact structures or other contact structures in contact region 112, which is not limited herein.

An end surface of second contact structure 410 that is on the first one of first layers 304 (e.g., first layer 304C) is flush with an end surface of third contact structure 408 that is on the first one of first layers 304 (e.g., first layer 304C). For example, a surface of a top end of second contact structure 410 that is on first layer 304C is flush with a surface of a top end of third contact structure 408 that is on the same first layer 304C. In some implementations, a size of the end surface of second contact structure 410 may be equal to a size of the end surface of third contact structure 408. The size of the end surface of second contact structure 410 or third contact structure 408 can be, for example, a diameter or an area of the end surface of second contact structure 410 or third contact structure 408. For example, as shown in FIG. 5R below, the end surface of second contact structure 410 may have a circular shape, and the end surface of third contact structure 408 may have the same circular shape. A diameter 599 of the end surface of second contact structure 410 may be equal to a diameter 597 of the end surface of third contact structure 408.

In some implementations, on first layer 304C, a size of the end surface of first contact structure 402 is greater than the size of the end surface of second contact structure 410 and the size of the end surface of third contact structure 408. The size of the end surface of first contact structure 402 can be, for example, a diameter or an area of the end surface of first contact structure 402. For example, as shown in FIG. 5R below, on the same first layer 304C, a diameter 598 of the circular end surface of first contact structure 402 is greater than diameter 599 of the circular end surface of second contact structure 410 and diameter 597 of the circular end surface of third contact structure 408.

Also on first layer 304C, the size of the end surface of isolation structure 404 is greater than the size of the end surface of second contact structure 410 and the size of the end surface of third contact structure 408. For example, the size of the end surface of isolation structure 404 may be a width 413 of isolation structure 404 as shown in FIG. 4B or FIG. 5R. Width 413 of isolation structure 404 may be greater than diameter 599 of the circular end surface of second contact structure 410 and diameter 597 of the circular end surface of third contact structure 408.

In some implementations, on first layer 304C, the size of the end surface of first contact structure 402 is equal to the size of the end surface of isolation structure 404. Alternatively, the size of the end surface of first contact structure 402 is different from the size of the end surface of isolation structure 404. For example, as shown in FIG. 5R, diameter 598 of the circular end surface of first contact structure 402 may be equal to or different from width 413 of isolation structure 404.

As described above with reference to FIGS. 4A-4C, vertical capacitor 274 may include (1) first electrode structure 403 coupled with a corresponding vertical transistor 172 and (2) second electrode structure 411 isolated from first electrode structure 403. On the same first layer 304C, an end surface of first electrode structure 403 is flush with at least one of the end surface of first contact structure 402, the end surface of isolation structure 404, the end surface of second contact structure 410, or the end surface of third contact structure 408. In some implementations, a size of the end surface of first electrode structure 403 is equal to the size of the end surface of second contact structure 410 and the size of the end surface of third contact structure 408. The size of the end surface of first electrode structure 403 can be, for example, a diameter or an area of the end surface of first electrode structure 403. For example, referring to FIG. 5R, on the same first layer 304C, a diameter 596 of the circular end surface of first electrode structure 403 is equal to diameter 599 of the circular end surface of second contact structure 410 and diameter 597 of the circular end surface of third contact structure 408.

With reference to FIG. 4A, first semiconductor structure 104 may further include a dielectric layer 406 covering at least one of memory cell array 130 in memory array region 110, isolation structure 404, or stack structure 302 in contact region 112. Dielectric layer 406 may include a dielectric material including, but not limited to, silicon oxide, silicon nitride, silicon oxynitride, or any combination thereof.

In some implementations, memory device 400 can further include any other suitable components that are not illustrated in FIGS. 4A-4C. For example, in some implementations, memory device 400 can further include one or more interconnect layers including interconnect structures to electrically connect the word lines, the bit lines, the first and second electrode structures of the capacitors, etc., to transfer electrical signals. In some implementations, the one or more interconnect layers can include lateral interconnect lines and vertical interconnect access (VIA) contacts. In some implementations, the one or more interconnect layers can also include local interconnects, such as bit line contacts, word line contacts, and capacitor contacts. As used herein, the term “interconnects” can broadly include any suitable types of interconnects, such as middle-end-of-line (MEOL) interconnects and back-end-of-line (BEOL) interconnects. The one or more interconnect layers can further include one or more interlayer dielectric (ILD) layers (also known as “intermetal dielectric (IMD) layers”) in which the interconnect lines and via contacts can form. That is, the one or more interconnect layers can include interconnect lines and via contacts in multiple ILD layers. The interconnects in the one or more interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

FIG. 4D illustrates another side view of cross sections of memory device 400, according to some aspects of the present disclosure. The cross sections in FIG. 4D may be along lines C-C and D-D shown in FIG. 4B. It is understood that FIG. 4D is for illustrative purposes only and may not necessarily reflect the actual device structure (e.g., interconnections) in practice. As an example of 3D memory device 100 described above with respect to FIGS. 1A-1B, memory device 400 can be a bonded chip including first semiconductor structure 104 and second semiconductor structure 102, where first semiconductor structure 104 is stacked over second semiconductor structure 102. First and second semiconductor structures 104 and 102 are jointed at bonding interface 106 therebetween, according to some implementations. As shown in FIG. 4D, second semiconductor structure 102 can include a substrate 470, which can include silicon (e.g., single crystalline silicon, c-Si), SiGe, GaAs, Ge, SOI, or any other suitable materials.

Second semiconductor structure 102 can include peripheral circuits 132 on substrate 470. In some implementations, peripheral circuits 132 include a plurality of transistors 474 (e.g., planar transistors and/or 3D transistors). Trench isolations (e.g., shallow trench isolations (STIs)) and doped regions (e.g., wells, sources, and drains of transistors 474) can be formed on or in substrate 470 as well.

In some implementations, second semiconductor structure 102 further includes an interconnect layer 476 above peripheral circuits 132 to transfer electrical signals to and from peripheral circuits 132. Interconnect layer 476 can include a plurality of interconnects (also referred to herein as “contacts”), including lateral interconnect lines and VIA contacts. Interconnect layer 476 can further include one or more ILD layers in which the interconnect lines, via contacts, and bonding contacts can form. That is, interconnect layer 476 can include interconnect lines, via contacts, and bonding contacts in multiple ILD layers. In some implementations, peripheral circuits 132 are coupled to one another through the interconnects in interconnect layer 476. The interconnects in interconnect layer 476 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

First semiconductor structure 104 can be bonded on top of second semiconductor structure 102 in a face-to-face manner at bonding interface 106. In some implementations, bonding interface 106 is a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously.

In some implementations, first semiconductor structure 104 further includes an interconnect layer 481 including bit lines 482, interconnect lines, via contacts, and bonding contacts to transfer electrical signals. Interconnect layer 481 can include a plurality of interconnects, such as MEOL interconnects and BEOL interconnects. In some implementations, the interconnects in interconnect layer 481 also include local interconnects, such as bit lines 482 (e.g., an example of bit lines 168 in FIG. 1B) and word line contacts (not shown). Interconnect layer 481 can further include one or more ILD layers in which the interconnect lines and via contacts can form. The interconnects in interconnect layer 481 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof. In some implementations, peripheral circuits 132 include a word line driver/row decoder coupled to the word line contacts in interconnect layer 481 through interconnect lines, via contacts, and bonding contacts in interconnect layers 476 and 481. In some implementations, peripheral circuits 132 include a bit line driver/column decoder coupled to bit lines 482 and bit line contacts (if any) in interconnect layer 481 through interconnect lines, via contacts, and bonding contacts in interconnect layers 476 and 481.

In some implementations, first semiconductor structure 104 includes a DRAM device in which memory cells are provided in the form of an array of DRAM cells above interconnect layer 481. The array of DRAM cells is provided in memory array region 110. First contact structure 402, second contact structure 410, third contact structure 408 (not shown in FIG. 4D), and a fourth contact structure 485 are provided in contact region 112. Fourth contact structure 485 may be coupled to second electrode structures 411 (e.g., the common electrode) of vertical capacitors 274 through third conductive layer 419. Isolation structure 404 is located between memory array region 110 and contact region 112.

The DRAM cell can include vertical transistor 172 and vertical capacitor 274 coupled to vertical transistor 172. In some implementations, one of source and drain (e.g., at the upper end in FIG. 4D) of vertical transistor 172 is coupled to vertical capacitor 274, and the other one of source and drain (e.g., at the lower end in FIG. 4D) of vertical transistor 172 is coupled to bit line 482. The DRAM cell can be a 1T1C cell including one transistor and one capacitor. It is understood that the DRAM cell may be of any suitable configurations, such as 2T1C cell, 3T1C cell, etc.

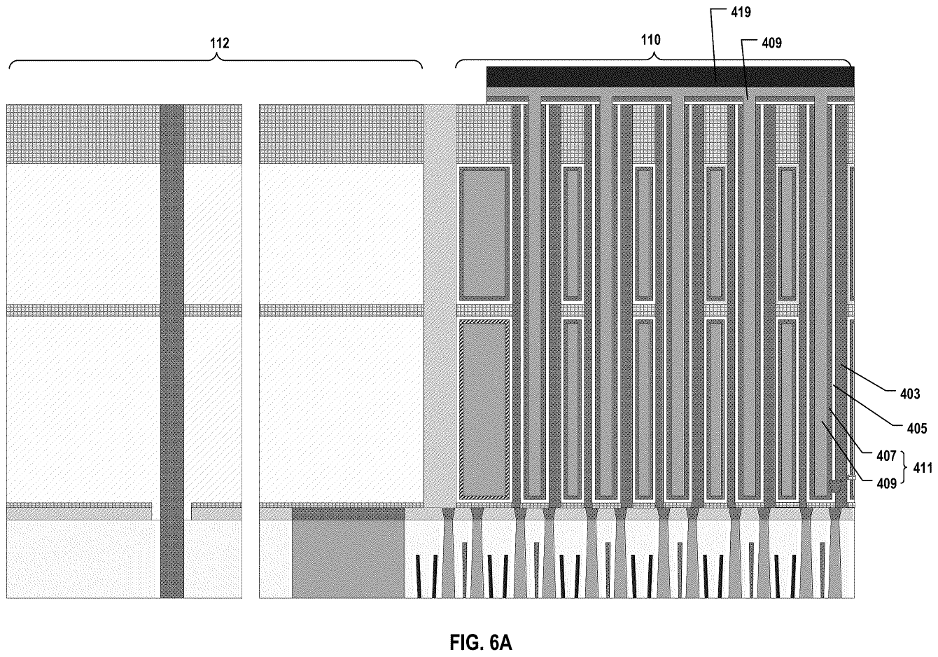

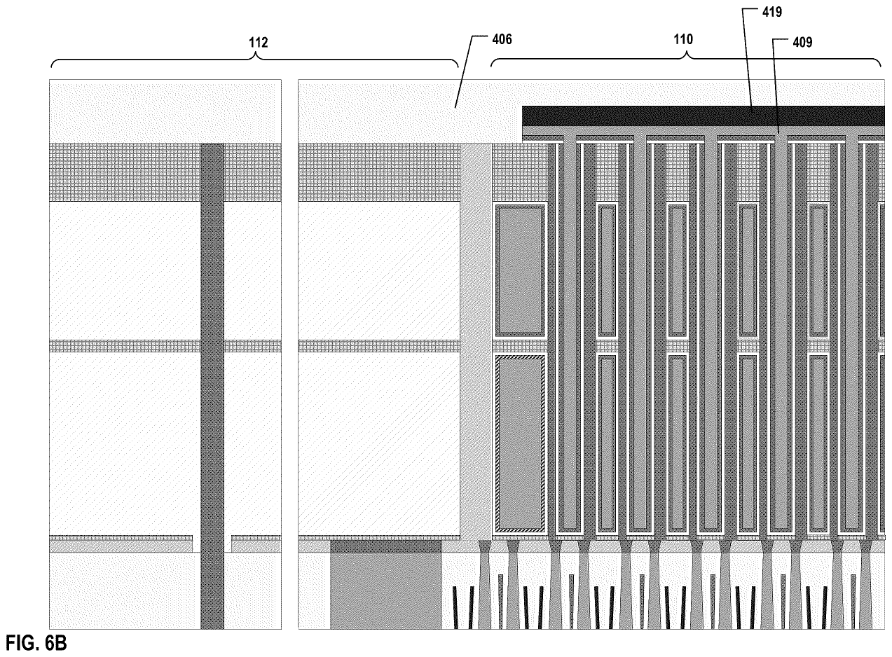

FIGS. 5A-5Z and 6A-6B illustrate a fabrication process for forming memory device 400, according to some aspects of the present disclosure. Referring to FIGS. 5A and 5B (e.g., FIG. 5B is a plan view of the structure of FIG. 5A), transistor structure 202 including an array of vertical transistors 172 is formed. In some implementations, forming transistor structure 202 may include forming a plurality of semiconductor bodies 175 extending vertically on a semiconductor layer. In some implementations, the plurality of semiconductor bodies 175 can be formed by patterning a semiconductor substrate using any suitable patterning processes (e.g., photoetching, dry etching, wet etching, cleaning, chemical mechanical polishing (CMP), etc.) to form trenches laterally extending along the x-direction and the y-direction, the remaining vertical portions of the semiconductor substrate between the trenches form the semiconductor bodies 175, and the remaining lateral portion of the semiconductor substrate below the trenches form the semiconductor layer. In some implementations, TISO structures 503 can be formed in the trenches to laterally separate adjacent semiconductor bodies 175.

Semiconductor bodies 175 can be used to form channels of vertical transistors 172. In some implementations, semiconductor bodies 175 can be formed by using any suitable semiconductor material, such as monocrystalline silicon, polycrystalline silicon, or silicon-germanium. In some other implementations, semiconductor bodies 175 can be formed by using any suitable metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc.

In some implementations, gate structures of vertical transistors 172 can be formed. For example, forming a gate structure includes forming a gate dielectric layer and forming a gate electrode 176. In some implementations, the gate dielectric layer and gate electrode 176 can be formed by any suitable deposition processes (e.g., chemical vapor deposition (CVD), physical vapor deposition (PVD), atomic layer deposition (ALD), etc.). In some implementations, forming the gate dielectric layer can include depositing any suitable dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, forming gate electrode 176 includes depositing one or more layers of conductive materials including, but not limited to, W, Co, Cu, Al, TiN, TaN, polysilicon, silicide, or any combination thereof.

In some implementations, forming transistor structure 202 further includes forming insulating layer 439 to fill the trenches between adjacent gate structures and/or adjacent semiconductor bodies 175. In some implementations, forming transistor structure 202 further includes forming SNC structures 480 on top of semiconductor bodies 175, respectively.

Next, stack structure 302 is formed on transistor structure 202. Stack structure 302 may be formed by depositing alternating first layers 304 (304A, 304B, 304C) and first dielectric layers 306 (306A, 306B) on transistor structure 202 across memory array region 110 and contact region 112, using one or more thin film deposition processes including, but not limited to, CVD, PVD, ALD, or any combination thereof. First dielectric layers 306 may include the same dielectric material, whereas first layers 304 may include the same dielectric material or different dielectric materials. The dielectric material(s) of first layers 304 may be different from the dielectric material of first dielectric layers 306. For example, first dielectric layers 306A and 306B may include silicon oxide. First layer 304A may include silicon nitride (SiN) or SiBN. First layer 304B may include SiCN. First layer 304C may include SiN or SiCN.

Hard masks 308 and 310 may be formed on top of stack structure 302. For example, hard mask 308 may include polysilicon, whereas hard mask 310 may include silicon oxide. Hard masks 308 and 310 may be formed using one or more thin film deposition processes including, but not limited to, CVD, PVD, ALD, or any combination thereof. Hard mask 310 may be etched to form openings 502 in memory array region 110 and openings 504 and 506 in contact region 112 (shown in FIG. 5B). In some implementations, fabrication processes for forming openings 502, 504, 506 include wet etching and/or dry etching, such as DRIE.

Referring to FIGS. 5C and 5D (e.g., FIG. 5D is a plan view of the structure of FIG. 5C), a photoresist layer 507 may be formed on top of hard mask 310. Photoresist layer 507 may be patterned to form a first trench opening 508 and an opening 510.

Referring to FIGS. 5E and 5F (e.g., FIG. 5F is a plan view of the structure of FIG. 5E), hard mask 310 may be etched through first trench opening 508 and opening 510 of photoresist layer 507 (shown in FIG. 5C) to form a second trench opening 512 and an opening 514 in hard mask 310, respectively. In some implementations, fabrication processes for forming second trench opening 512 and opening 514 include wet etching and/or dry etching, such as DRIE. Photoresist layer 507 shown in FIG. 5C is removed to expose openings 502, 504, and 506.

Referring to FIG. 5G, hard mask 308 may be etched through opening 502, second trench opening 512, and opening 514 of hard mask 310 (shown in FIGS. 5E-5F) to form an opening 516, a third trench opening 518, and an opening 520 in hard mask 308, respectively. Meanwhile, hard mask 308 may also be etched through opening 504 and opening 506 of hard mask 310 (shown in FIGS. 5E-5F) to form a first corresponding opening and a second corresponding opening in hard mask 308, respectively. In some implementations, fabrication processes for forming the openings in hard mask 308 include wet etching and/or dry etching, such as DRIE. Hard mask 310 can be removed after forming the openings in hard mask 308.

Referring to FIGS. 5H and 5I (e.g., FIG. 5I is a plan view of the structure of FIG. 5H), stack structure 302 may be etched through opening 516, third trench opening 518, and opening 520 of hard mask 308 (shown in FIG. 5G) to form a storage opening 522, an isolation opening 524, and a first contact opening 526 in stack structure 302, respectively. Transistor structure 202 may also be etched such that first contact opening 526 may also extend through transistor structure 202. Meanwhile, stack structure 302 may also be etched through the first corresponding opening and the second corresponding opening in hard mask 308 of FIG. 5G to form a second contact opening 528 and a third contact opening 530 in stack structure 302, respectively. In some implementations, fabrication processes for forming the openings in stack structure 302 include wet etching and/or dry etching, such as DRIE. Hard mask 308 can be removed after forming the openings in stack structure 302.

First, second, third contact openings 526, 528, and 530 may be located in contact region 112. Storage opening 522 may be located in memory array region 110. Isolation opening 524 may be located between memory array region 110 and contact region 112, and may surround memory array region 110. In some implementations, isolation opening 524 may have a trench shape.

Referring to FIG. 5J, a sacrificial layer 533 may be deposited on stack structure 302 (e.g., on top of first layer 304C). Openings 522, 524, 526, 528, and 530 in stack structure 302 may be filled with sacrificial layer 533. For example, sacrificial layer 523 different from first layers 304 and first dielectric layers 306, such as a polysilicon layer or a carbon layer, is deposited into openings 522, 524, 526, 528, and 530 and on top of first layer 304C using one or more thin film deposition processes, such as CVD, PVD, ALD, or any combination thereof.

Referring to FIGS. 5K and 5L (e.g., FIG. 5L is a plan view of the structure of FIG. 5K), sacrificial layer 523 can be patterned using lithography and wet etching and/or dry etching to remove a part of sacrificial layer 523 in isolation opening 524 to expose isolation opening 524. Meanwhile, another part of sacrificial layer 523 in contact region 112 may also be removed.

Referring to FIGS. 5M and 5N (e.g., FIG. 5N is a plan view of the structure of FIG. 5M), isolation structure 404 may be formed in isolation opening 524 by depositing a dielectric material into isolation opening 524 using one or more thin film deposition processes including, but not limited to, CVD, PVD, ALD, or any combination thereof. The dielectric material of isolation structure 404 may include silicon nitride, silicon oxynitride, SiCN, or SiBN, or any combination thereof.

Referring to FIGS. 5O and 5P (e.g., FIG. 5P is a plan view of the structure of FIG. 5O), sacrificial layer 523 shown in FIG. 5M may be completely removed using wet etching and/or dry etching to expose storage opening 522, first contact opening 526, second contact opening 528, and third contact opening 530.

Referring to FIGS. 5Q and 5R (e.g., FIG. 5R is a plan view of the structure of FIG. 5Q), first electrode structure 403 of vertical capacitor 274 can be formed in storage opening 522 (shown in FIG. 5O), first contact structure 402 may be formed in first contact opening 526 (shown in FIG. 5O), second contact structure 410 may be formed in second contact opening 528 (shown in FIG. 5O), and third contact structure 408 may be formed in third contact opening 530 (shown in FIG. 5O). For example, first electrode structure 403, first contact structure 402, second contact structure 410, and third contact structure 408 may be formed by depositing one or more conductive layers into storage opening 522, first contact opening 526, second contact opening 528, and third contact opening 530, respectively, using one or more thin film deposition processes such as CVD, PVD, ALD, or any combination thereof. In one example, the one or more conductive layers may include a TiN layer.

It is contemplated that one or more other contact structures or dummy contact structures extending through stack structure 302 in the z direction can also be formed in contact region 112, by performing operations like those described above for forming first contact structure 402 or those described above for forming second and third contact structures 410 and 408.

Referring to FIGS. 5S and 5T (e.g., FIG. 5T is a plan view of the structure of FIG. 5S), a mesh hard mask 532 can be deposited on top of stack structure 302 of FIG. 5Q. A photoresist layer 534 can be deposited on top of mesh hard mask 532. Photoresist layer 534 may be patterned to form openings 536 to expose mesh hard mask 532 through openings 536 in memory array region 110.

Referring to FIGS. 5U and 5V (e.g., FIG. 5V is a plan view of the structure of FIG. 5U), portions of mesh hard mask 532 exposed by photoresist layer 534 may be etched to expose first layer 304C. The exposed portions of first layer 304C can be etched away to form first mesh openings 538 in memory array region 110 using wet etching and/or dry etching, such as DRIE.

Referring to FIG. 5W, a first part of first dielectric layer 306B in memory array region 110 can be removed through first mesh openings 538 to form a first recess 540 using wet etching and/or dry etching, such as DRIE. A remaining part of first dielectric layer 306B in contact region 112 is isolated by isolation structure 404 and remains intact.

Referring to FIG. 5X, with mesh hard mask 532, portions of first layer 304B can also be etched away to form second mesh openings 542 in memory array region 110 using wet etching and/or dry etching, such as DRIE.

Referring to FIG. 5Y, a first part of first dielectric layer 306A in memory array region 110 can be removed through second mesh openings 542 to form a second recess 544 using wet etching and/or dry etching, such as DRIE. A remaining part of first dielectric layer 306A in contact region 112 is isolated by isolation structure 404 and remains intact. Therefore, a storage recess is formed in memory array region 110, which includes first meshing openings 538, first recess 540, second meshing openings 542, and second recess 544.

Referring to FIG. 5Z, second electrode structures 411 which are isolated from first electrode structures 403 are formed in the storage recess at least by: forming a storage dielectric layer 405 to cover first electrode structures 403 in the storage recess; and forming second electrode structures 411 in the storage recess by depositing a first conductive layer 407 (e.g., a TiN layer) and a second conductive layer 409 (e.g., a GeSi layer) over storage dielectric layer 405. For example, second electrode structures 411 can be formed by depositing a high-k dielectric layer to cover first electrode structures 403 and depositing a TiN layer and a GeSi layer over the high-k dielectric layer, using one or more thin film deposition processes such as CVD, PVD, ALD, or any combination thereof. Storage dielectric layer 405, first conductive layer 407, and second conductive layer 409 may extend across memory array region 110 and contact region 112. A third conductive layer 419 (e.g., a W layer) may also be formed over second conductive layer 409. Third conductive layer 419 may also extend across memory array region 110 and contact region 112.

Referring to FIG. 6A, a part of storage dielectric layer 405, a part of first conductive layer 407, a part of second conductive layer 409, and a part of third conductive layer 419, which are in contact region 112 and over isolation structure 404, may be etched away using dry etching and/or wet etching.

Referring to FIG. 6B, a dielectric layer 406 may be formed by depositing a dielectric material (e.g., silicon oxide) across contact region 112 and memory array region 110 (e.g., over stack structure 302 in contact region 112, isolation structure 404, and third conductive layer 419 in memory array region 110), using one or more thin film deposition processes such as CVD, PVD, ALD, or any combination thereof. Chemical Mechanical Planarization (CMP) may be performed on dielectric layer 406.

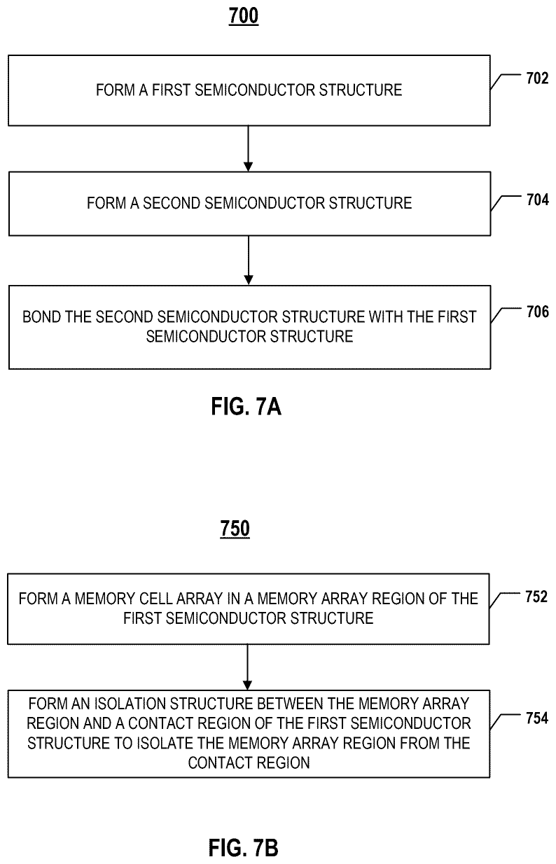

FIG. 7A illustrates a flowchart of a method 700 for forming a 3D memory device, according to some aspects of the present disclosure. The 3D memory device can be any memory device disclosed herein such as memory device 100, 160, or 400. It is understood that the operations shown in method 700 are not exhaustive and that other operations can be performed as well before, after, or between any of the illustrated operations. Further, some of the operations may be performed simultaneously, or in a different order than shown in FIG. 7A.

As shown in FIG. 7A, method 700 can start at operation 702, in which a first semiconductor structure can be formed. For example, first semiconductor structure 104 can be formed by performing operations like those described above with reference to FIGS. 5A-5Z and 6A-6B.

As shown in FIG. 7A, method 700 can proceed to operation 704, in which a second semiconductor structure can be formed. In some implementations, second semiconductor structure 102 of FIG. 1A or FIG. 4D can be formed. For example, with reference to FIG. 4D, peripheral circuits 132 can be formed on substrate 470. Interconnect layer 476 may be formed above peripheral circuits 132 to transfer electrical signals to and from peripheral circuits 132.

As shown in FIG. 7A, method 700 can proceed to operation 706, in which the second semiconductor structure can be bonded with the first semiconductor structure. For example, as shown in FIG. 4D, first semiconductor structure 104 and second semiconductor structure 102 can be bonded using hybrid bonding.

FIG. 7B illustrates a flowchart of a method 750 for forming a first semiconductor structure (e.g., first semiconductor structure 104), according to some aspects of the present disclosure. It is understood that the operations shown in method 750 are not exhaustive and that other operations can be performed as well before, after, or between any of the illustrated operations. Further, some of the operations may be performed simultaneously, or in a different order than shown in FIG. 7B.

As shown in FIG. 7B, method 750 can start at operation 752, in which a memory cell array can be formed in a memory array region of the first semiconductor structure. For example, an array of transistors can be formed in the memory array region. An array of storage units which connect to corresponding transistors can be formed in memory array region.

As shown in FIG. 7B, method 750 can proceed to operation 754, in which an isolation structure can be formed between the memory array region and a contact region of the first semiconductor structure to isolate the memory array region from the contact region. For example, the isolation structure isolates the array of storage units in the memory array region from the contact region.

In some implementations, forming the first semiconductor structure in method 750 further includes forming a stack structure including alternating first layers and first dielectric layers across the memory array region and the contact region. For example, stack structure 302 including alternating first layers 304 and first dielectric layers 306 can be formed by performing operations like those described above with reference to FIG. 5A.

In some implementations, forming the first semiconductor structure in method 750 further includes: forming a first contact opening, a second contact opening, and a third contact opening extending through the stack structure in a first direction in the contact region; forming storage openings extending through the stack structure in the first direction in the memory array region; and forming an isolation opening extending through the stack structure in the first direction between the memory array region and the contact region. For example, first contact opening 526, second contact opening 528, third contact opening 530, storage openings 522, and isolation opening 524 can be formed by performing operations like those described above with reference to FIGS. 5A-5I.

In some implementations, forming the isolation structure in operation 754 includes forming the isolation structure in the isolation opening. For example, isolation structure 404 may be formed in isolation opening 524 by performing operations like those describe above with reference to FIGS. 5J-5N.

In some implementations, forming the first semiconductor structure in method 750 further includes: forming a first contact structure in the first contact opening; forming a second contact structure in the second contact opening to couple to a word line; and forming a third contact structure in the third contact opening to couple to a bit line. An end surface of the first contact structure that is on a first one of the first layers is flush with an end surface of the isolation structure that is on the first one of the first layers. An end surface of the second contact structure that is on the first one of the first layers is flush with an end surface of the third contact structure that is on the first one of the first layers. For example, first contact structure 402, second contact structure 410, and third contact structure 408 can be formed by performing operations like those described above with reference to FIGS. 5O-5R. An end surface of first contact structure 402 that is on first layer 304C is flush with an end surface of isolation structure 404 that is on first layer 304C. An end surface of second contact structure 410 that is on first layer 304C is flush with an end surface of third contact structure 408 that is on first layer 304C.

In some implementations, the storage units include vertical capacitors, and forming the array of storage units in operation 752 includes forming first electrode structures in the storage openings, respectively. The first electrode structures are coupled with the transistors, respectively. Forming the array of storage units in operation 752 further includes forming second electrode structures isolated from the first electrode structures. The vertical capacitor includes a corresponding first electrode structure and a corresponding second electrode structure. For example, first electrode structures 403 can be formed in storage openings 522 by performing operations like those described above with reference to FIGS. 5O-5R. Second electrode structures 411 can be formed by performing operations like those described above with reference to FIGS. 5S-5Z and 6A.

In some implementations, forming the second electrode structures isolated from the first electrode structures includes forming a storage recess in the memory array region; and forming the second electrode structures isolated from the first electrode structures in the storage recess.

In some implementations, forming the storage recess in the memory array region includes: forming first mesh openings extending through a first one of the first layers in the memory array region; removing a first part of a first one of the first dielectric layers in the memory array region through the first mesh openings, where a remaining part of the first one of the first dielectric layers in the contact region is isolated by the isolation structure and remains intact; forming second mesh openings extending through a second one of the first layers in the memory array region; and removing a part of a second one of the first dielectric layers in the memory array region through the second mesh openings, where a remaining part of the second one of the first dielectric layers in the contact region is isolated by the isolation structure and remains intact.

For example, first mesh openings 538 extending through first layer 304C can be formed in memory array region 110, by performing operations like those described above with reference to FIGS. 5S-5V. A first part of first dielectric layer 306B in memory array region 110 can be removed through first mesh openings 538, by performing operations like those described above with reference to FIG. 5W. A remaining part of first dielectric layer 306B in contact region 112 is isolated by isolation structure 404 and remains intact, as shown in FIG. 5W. Second mesh openings 542 extending through first layer 304B are formed in memory array region 110, by performing operations like those described above with reference to FIG. 5X. A part of first dielectric layer 306A in memory array region 110 is removed through second mesh openings 542, by performing operations like those described above with reference to FIG. 5Y. A remaining part of first dielectric layer 306A in contact region 112 is isolated by isolation structure 404 and remains intact, as shown in FIG. 5Y.

In some implementations, forming the second electrode structures isolated from the first electrode structures includes: forming a storage dielectric layer to cover the first electrode structures in the storage recess; and forming the second electrode structures in the storage recess by depositing conductive layers over the storage dielectric layer. For example, storage dielectric layer 405 can be formed by performing operations like those described above with reference to FIGS. 5Z and 6A. Conductive layers 407 and 409 of second electrode structures 411 can be formed by performing operations like those described above with reference to FIGS. 5Z and 6A. Conductive layer 419 may also be formed to cover conductive layer 409, as shown in FIGS. 5Z and 6A.

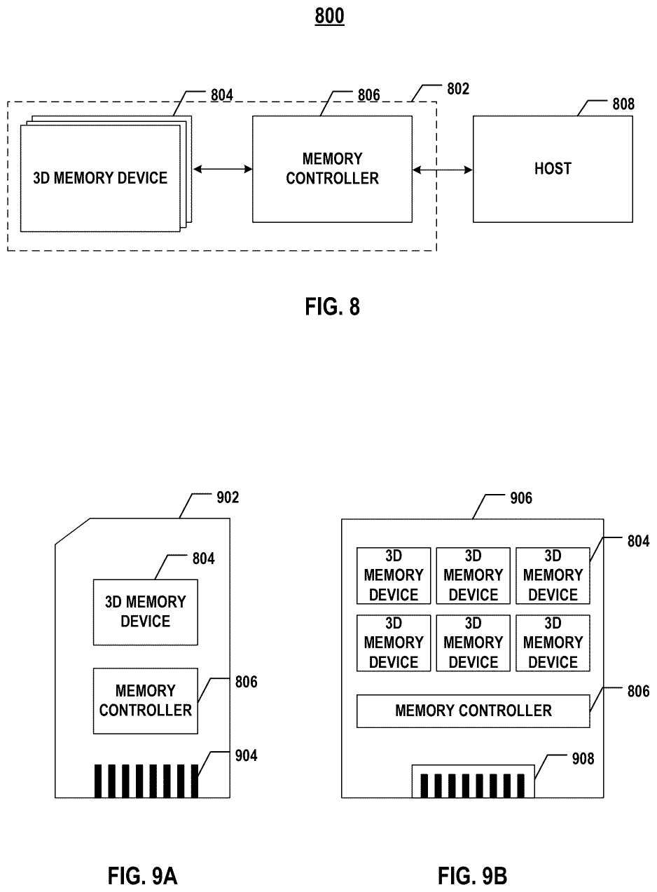

FIG. 8 illustrates a block diagram of an exemplary system 800 having a 3D memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more 3D memory devices 804 and a memory controller 806. Host 808 can be a processor of an electronic device, such as a central processing unit (CPU), or a system-on-chip (SoC), such as an application processor (AP). Host 808 can be configured to send or receive data to or from 3D memory devices 804.

3D memory device 804 can be any 3D memory device disclosed herein, such as 3D memory device 100 of FIG. 1A, memory device 160 of FIG. 1B, or memory device 400 of FIGS. 4A-4D. In some implementations, 3D memory device 804 includes a NAND Flash memory or a DRAM memory device.

Memory controller 806 (a.k.a., a controller circuit) is coupled to 3D memory device 804 and host 808 and is configured to control 3D memory device 804, according to some implementations. For example, memory controller 806 may be configured to operate the plurality of channel structures via the word lines. Memory controller 806 can manage the data stored in 3D memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804. Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 9A, memory controller 806 and a single 3D memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 electrically coupling memory card 902 with a host (e.g., host 808 in FIG. 8). In another example as shown in FIG. 9B, memory controller 806 and multiple 3D memory devices 804 may be integrated into an SSD 906. SSD 906 can further include an SSD connector 908 electrically coupling SSD 906 with a host (e.g., host 808 in FIG. 8). In some implementations, the storage capacity and/or the operation speed of SSD 906 is greater than those of memory card 902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a first semiconductor structure comprising:
a memory cell array in a memory array region of the first semiconductor structure, comprising:
an array of transistors; and
an array of storage units which connect to corresponding transistors; and
an isolation structure located between the memory array region and a contact region of the first semiconductor structure, wherein the isolation structure isolates the array of storage units in the memory array region from the contact region.

2. The memory device of claim 1, wherein the first semiconductor structure further comprises:
a stack structure comprising alternating first layers and first dielectric layers in the contact region.

3. The memory device of claim 2, wherein the first dielectric layers comprise a first dielectric material, and the first layers comprise second dielectric layers that comprise a second dielectric material.

4. The memory device of claim 2, wherein:
the first dielectric layers comprise a first dielectric material; and
the first layers comprise at least a second dielectric layer that comprises a second dielectric material and a third dielectric layer that comprises a third dielectric material.

5. The memory device of claim 2, wherein the first semiconductor structure further comprises:
a first contact structure extending through the stack structure in a first direction, wherein an end surface of the first contact structure that is on a first one of the first layers is flush with an end surface of the isolation structure that is on the first one of the first layers.

6. The memory device of claim 5, wherein the first semiconductor structure further comprises:
a second contact structure extending through the stack structure in the first direction and coupled to a word line; and
a third contact structure extending through the stack structure in the first direction and coupled to a bit line,
wherein an end surface of the second contact structure that is on the first one of the first layers is flush with an end surface of the third contact structure that is on the first one of the first layers.

7. The memory device of claim 6, wherein a size of the end surface of the second contact structure is equal to a size of the end surface of the third contact structure.

8. The memory device of claim 6, wherein:
a size of the end surface of the first contact structure is greater than the size of the end surface of the second contact structure and the size of the end surface of the third contact structure; or
the size of the end surface of the isolation structure is greater than the size of the end surface of the second contact structure and the size of the end surface of the third contact structure.

9. The memory device of claim 5, wherein a size of the end surface of the first contact structure is equal to a size of the end surface of the isolation structure.

10. The memory device of claim 5, wherein a size of the end surface of the first contact structure is different from a size of the end surface of the isolation structure.

11. The memory device of claim 5, wherein the isolation structure comprises a dielectric material, and the first contact structure comprises a conductive material.

12. The memory device of claim 1, further comprising:
a second semiconductor structure bonded with the first semiconductor structure,
wherein the second semiconductor structure comprises a peripheral circuit coupled with the memory cell array.

13. The memory device of claim 6, wherein the transistors comprise vertical transistors, and the storage units comprise vertical capacitors.

14. The memory device of claim 13, wherein the vertical capacitor comprises:
a first electrode structure coupled with a corresponding vertical transistor; and
a second electrode structure isolated from the first electrode structure,
wherein an end surface of the first electrode structure that is on the first one of the first layers is flush with the end surface of the second contact structure and the end surface of the third contact structure.

15. The memory device of claim 14, wherein a size of the end surface of the first electrode structure is equal to a size of the end surface of the second contact structure and a size of the end surface of the third contact structure.

16. A memory device, comprising:
a first semiconductor structure comprising:
a memory cell array in a memory array region of the first semiconductor structure, comprising:
an array of vertical transistors; and
an array of vertical capacitors which connect to corresponding vertical transistors;
a stack structure comprising alternating first layers and first dielectric layers in a contact region of the first semiconductor structure; and
an isolation structure located between the memory array region and the contact region to isolate the array of vertical capacitors from the stack structure.

17. A method for forming a memory device, comprising:
forming a first semiconductor structure at least by:
forming a memory cell array in a memory array region of the first semiconductor structure, comprising:
forming an array of transistors in the memory array region; and
forming, in the memory array region, an array of storage units which connect to corresponding transistors; and
forming an isolation structure between the memory array region and a contact region of the first semiconductor structure to isolate the array of storage units in the memory array region from the contact region.

18. The method of claim 17, wherein forming the first semiconductor structure further comprises:
forming a stack structure comprising alternating first layers and first dielectric layers across the memory array region and the contact region;
forming a first contact opening, a second contact opening, and a third contact opening extending through the stack structure in a first direction in the contact region;
forming storage openings extending through the stack structure in the first direction in the memory array region; and
forming an isolation opening extending through the stack structure in the first direction between the memory array region and the contact region.

19. The method of claim 18, wherein forming the isolation structure comprises forming the isolation structure in the isolation opening, and
wherein forming the first semiconductor structure further comprises:
forming a first contact structure in the first contact opening;
forming a second contact structure in the second contact opening to couple to a word line; and
forming a third contact structure in the third contact opening to couple to a bit line,
wherein an end surface of the first contact structure that is on a first one of the first layers is flush with an end surface of the isolation structure that is on the first one of the first layers, and
wherein an end surface of the second contact structure that is on the first one of the first layers is flush with an end surface of the third contact structure that is on the first one of the first layers.

20. The method of claim 18, wherein the storage units comprise vertical capacitors, and forming the array of storage units comprises:
forming first electrode structures in the storage openings, respectively, wherein the first electrode structures are coupled with the transistors, respectively; and
forming second electrode structures isolated from the first electrode structures,
wherein each vertical capacitor comprises a corresponding first electrode structure and a corresponding second electrode structure.
